(19) United States
(12) Patent Application Publication
(10) Pub. No.: US 2025/0204190 A1
(43) Pub. Date: Jun. 19, 2025

(54) DISPLAY DEVICE

(71) Applicant: LG DISPLAY CO., LTD., Seoul (KR)

(72) Inventors: Min Ki KIM, Paju-si (KR); Hye Min HWANG, Paju-si (KR); Jae Hwan MYUNG, Paju-si (KR)

(73) Assignee: LG DISPLAY CO., LTD., Seoul (KR)

(21) Appl. No.: 18/778,764

(22) Filed: Jul. 19, 2024

(30) Foreign Application Priority Data
Dec. 13, 2023 (KR) 10-2023-0180748

(51) Int. Cl. H10K 59/38; H10K 59/35; H10K 102/00

(52) U.S. Cl. CPC H10K 59/38; H10K 59/351; H10K 2102/351

(57) ABSTRACT

In the present disclosure, a display device is disclosed. The display device may include a substrate, a plurality of light emitting elements disposed on the substrate, and a plurality of color filters disposed on the plurality of light emitting elements and having different thicknesses. Each of the plurality of color filters includes a metal layer including a first external metal layer and a second external metal layer, and a dielectric layer disposed between the first external metal layer and the second external metal layer. According to the display device of example arrangements, it is possible to improve a color gamut.

### CROSS-REFERENCE TO RELATED APPLICATION

This application claims priority to and the benefit of Korean Patent Application No. 10-2023-0180748, filed on Dec. 13, 2023, the disclosure of which is incorporated herein by reference in its entirety.

### BACKGROUND

### 1. Technical Field

The present specification relates to a display device.

### 2. Discussion of the Related Art

In the recent information age, a display field in which electrical information signals are visually expressed has developed rapidly, and in response thereto, various display devices having excellent performance, such as thinness, light weight, and low power consumption, are being developed. Display devices include liquid crystal display (LCD) devices, field emission display (FED) devices, organic light emitting diode (OLED) display devices, and the like.

As light emitting elements, light emitting elements capable of emitting light having various wavelengths may be used. The formation of an organic light emitting layer is essential to form light emitting elements that emit light having different wavelengths, and a fine metal mask (FMM) is used to form the organic light emitting layer. Red, green, and blue organic light emitting layers are each deposited in a sub-pixel using the FMM. As an OLED display device becomes larger or has an increased resolution, sagging of a substrate and the FMM occurs, and thus it is difficult to form the red, green, and blue organic light emitting layers using the FMM.

### SUMMARY

Accordingly, embodiments of the present disclosure are directed to a display device that substantially obviates one or more of the problems due to limitations and disadvantages of the related art.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device may comprise a substrate, a plurality of light emitting elements disposed on the substrate, and a plurality of color filters disposed on the plurality of light emitting elements and having different thicknesses, wherein each of the plurality of color filters may include a metal layer including a first external metal layer and a second external metal layer, and a dielectric layer disposed between the first external metal layer and the second external metal layer.

The dielectric layer may be disposed in contact with the first external metal layer and the second external metal layer and may contain a transparent conductive oxide.

The dielectric layer may include a first dielectric layer disposed between the first external metal layer and the internal metal layer, and a second dielectric layer disposed between the internal metal layer and the second external metal layer.

The plurality of color filters may include a first color filter, a second color filter, and a third color filter, each of which implements any one of red, green, and blue in a non-overlapping manner, and a thickness of the first external metal layer of the second color filter may be 50% to 150% of a thickness of the first external metal layer of the first color filter.

The plurality of light emitting elements may include a first light emitting element corresponding to the first color filter, a second light emitting element corresponding to the second color filter, a third light emitting element corresponding to the third color filter, and a fourth light emitting element implementing a white color.

The metal layer may include a thickness stepped portion disposed between the color filters having different thicknesses or disposed to overlap at least one of the color filters having different thicknesses in a thickness direction.

A transmittance distribution graph of light emitted from the light emitting element and passing through the color filter may include a first full width at half maximum (FWHM), a transmittance distribution graph of light emitted from the light emitting element and passing through the first external metal layer and the dielectric layer may include a second FWHM, and the first FWHM may be smaller than the second FWHM.

Light emitted from the plurality of light emitting elements may sequentially pass through the first external metal layer, the dielectric layer, and the second external metal layer.

Each of the plurality of light emitting elements may include an organic light emitting layer.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1 is a block diagram showing a display device according to one embodiment of the present specification.

FIG. 2 is a schematic plan view showing a pixel according to an embodiment of the present specification.

FIG. 3 is a schematic plan view showing a pixel according to another embodiment of the present specification.

FIG. 4 is a schematic plan view showing a pixel according to still another embodiment of the present specification.

FIG. 5 is a schematic cross-sectional view showing one example of a cross-sectional structure of a pixel along line I-I of FIG. 2 in a top emission type display panel.

FIG. 6 is a schematic cross-sectional view showing one example of a cross-sectional structure of a pixel along line I-I of FIG. 2 in a bottom emission type display panel.

FIG. 7 is a cross-sectional view showing another example of the cross-sectional structure of the pixel along line I-I of FIG. 2.

FIG. 8 is a cross-sectional view showing the cross-sectional structure of the pixel according to another embodiment of the present specification.

FIG. 9 is a simulation graph showing transmittance distribution by wavelength band according to the thickness of a metal when light is radiated onto the metal.

FIG. 10 is a simulation graph showing transmittance distribution by wavelength bands for different metals having the same thickness.

FIG. 11 is a simulation graph showing a change in peak wavelength depending on the presence or absence of a dielectric layer.

FIG. 12 is a simulation graph showing a change in transmittance distribution of light passing through a single layer or a plurality of metal layers.

FIG. 13 is a cross-sectional view showing a color filter according to a first embodiment of the present specification.

FIG. 14 is a cross-sectional view showing a color filter according to a second embodiment of the present specification.

FIG. 15 is a cross-sectional view showing a color filter according to a third embodiment of the present specification.

FIG. 16 is a cross-sectional view showing the relationship between color filters that implement colors of red, green, and blue in the present specification.

FIGS. 17 to 23 are schematic cross-sectional views for describing a thickness step of a metal layer according to various embodiments of the present specification.

FIG. 24 is a simulation graph showing transmittance distribution by wavelength band according to the thickness of a dielectric layer when light is radiated to the color filter.

FIG. 25 is a simulation graph showing transmittance distribution by wavelength band of light emitted from each sub-pixel included in a pixel according to another embodiment of the present specification.

FIG. 26 is a view schematically showing a virtual reality device.

FIG. 27 is a block diagram showing a display device according to one embodiment of the present specification.

FIG. 28 is a view specifically showing a display driving unit and a display panel shown in FIG. 27.

FIG. 29 is a view showing a distance between first and second display panels shown in FIG. 28.

### DETAILED DESCRIPTION

Advantages and features of the present specification and methods for achieving them will become clear with reference to embodiments described below in detail in conjunction with the accompanying drawings. The present disclosure is not limited to the embodiments disclosed below but can be implemented in various different forms, these embodiments are merely provided to make the disclosure of the present disclosure complete and fully inform those skilled in the art to which the present disclosure pertains of the scope of the present disclosure, and the present disclosure is only defined by the scope of the appended claims.

In describing the present invention, when it is determined that the detailed description of a related known technology may unnecessarily obscure the gist of the present invention, detailed description thereof will be omitted.

When the terms “comprise,” “include,” “have,” and “consist of” described in the present specification are used, other parts may be added unless “only” is used. When a component is expressed in the singular, it can be construed as a plurality of components unless specifically stated otherwise.

When the position relationship and interconnection relationship between two components, such as “on,” “above,” “under,” “next to,” “connected or coupled,” “crossing or intersecting,” or the like described, one or more other components may be interposed between the components unless the term “immediately” or “directly” is described.

When the temporal relationship is described using the term “after,” “subsequently,” “then,” “before,” or the like, it may include a non-consecutive case unless the term “immediately” or “directly” is used.

Although the term “first,” “second,” or the like may be used to distinguish components, functions or structures of the components are not limited by the ordinal number or component name added to the front of the component.

The following embodiments may be partially or fully coupled or combined, and various technological interworking and driving are possible. The embodiments may be implemented independently of each other and implemented together in the associated relationship.

In addition, terms (including technical and scientific terms) used in embodiments of the present specification may be construed as meaning that may be generally understood by those skilled in the art to which the present specification pertains unless explicitly specifically defined and described, and the meanings of the commonly used terms, such as terms defined in a dictionary, may be construed in consideration of contextual meanings of related technologies.

Hereinafter, embodiments of the present invention will be described in detail with reference to the accompanying drawings.

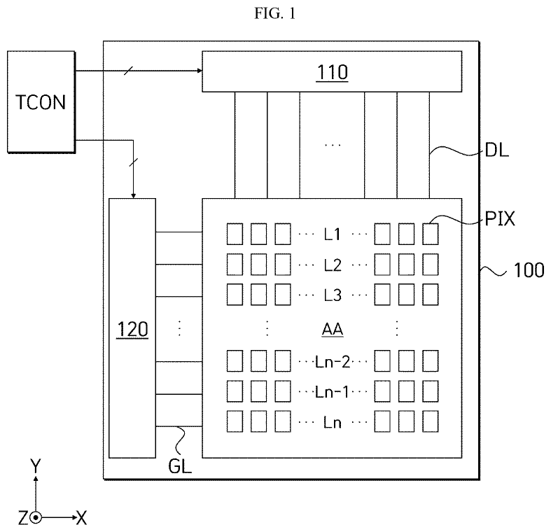

FIG. 1 is a block diagram showing a display device according to one embodiment of the present specification.

Referring to FIG. 1, a display device may include a display panel 100 in which a plurality of pixels PIX are disposed in a display area and a display panel driving unit for driving the pixels PIX.

The display panel 100 may be, but is not limited to, a panel having a rectangular structure having the length in an X-axis direction, the width in a Y-axis direction, and the thickness in a Z-axis direction or may have an irregular shape in which at least a portion includes a circular or elliptical shape.

In the display panel 100, the display area in which input images are displayed may be a screen that is visible from the front of the display panel 100. The screen of the display panel 100 may include a pixel array AA which displays images and on which a plurality of pixels PIX are disposed. The pixels PIX may include a plurality of sub-pixels that implement different colors. The pixel array AA may include pixel lines LI to Ln on which pixel data is written by being sequentially scanned with a scan pulse shifted in a scanning direction.

The input images may be displayed on the sub-pixels disposed in the display area of the display panel 100. Each of the sub-pixels may include a light emitting element, a pixel circuit for driving the light emitting element, and color filters that implement colors by converting the wavelength of light emitted from the light emitting element.

The light emitting element may be a light emitting diode (LED). The light emitting element may be an organic light emitting diode (OLED). The light emitting element is a light emitting element for backlight and may be a backlight unit.

On the display panel 100, a plurality of gate lines GL and a plurality of data lines DL may be disposed to intersect each other. Each of the sub-pixels may be connected to the gate line GL and the data line DL.

The display panel driving unit may include a data driver 110, a gate driver 120, and a timing controller TCON for controlling the gate driver 120 and the data driver 110.

The data driver 110 may convert image data received from the timing controller TCON into gamma compensation voltages in response to a data control signal provided from the timing controller TCON and output data voltages. The data voltages output from the data driver 110 may be supplied to the data lines DL.

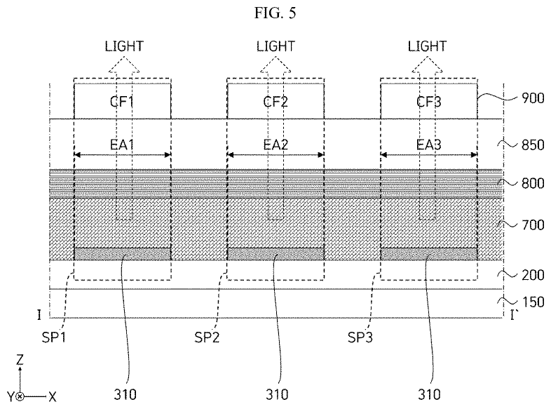

The gate driver 120 may supply scan signals to scan lines SL in response to a gate control signal provided from the timing controller TCON. The gate driver 120 may be disposed in at least a non-display area NA of the display panel 100 as shown in FIG. 1 or disposed in a display area as shown in FIG. 5.

The timing controller TCON may align image data input from the outside and supply the aligned image data to the data driver 110. The timing controller TCON may generate the gate control signal and the data control signal based on timing signals synchronized with the input image signal, such as a dot clock signal, a data enable signal, and horizontal/vertical synchronization signals. The timing controller TCON may control operation timings of the gate driver 120 and the data driver 110 by supplying the gate control signal to the gate driver 120 and supplying the data control signal to the data driver 110.

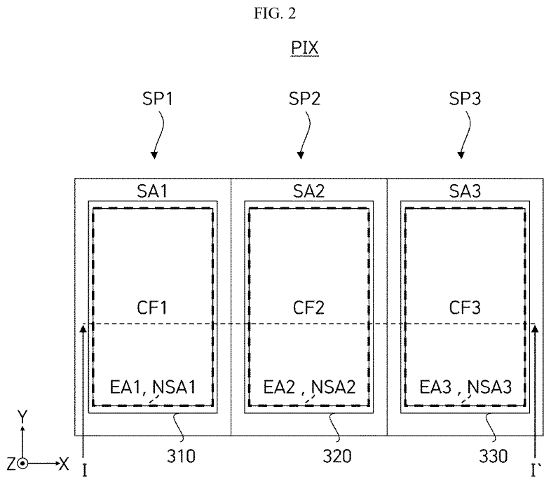

FIG. 2 is a schematic plan view showing a pixel according to an embodiment of the present specification.

Referring to FIG. 2, the pixel PIX may include a plurality of sub-pixels SP1, SP2, and SP3.

The plurality of sub-pixels SP1, SP2, and SP3 may include a first sub-pixel SP1, a second sub-pixel SP2, and a third sub-pixel SP3 that are arranged in a first direction (e.g., an X direction), but are not limited thereto.

The first sub-pixel SP1 may include a first light emitting element, a first pixel circuit for driving the first light emitting element, and a first color filter CF1 that implements a color by converting the wavelength of light emitted from the first light emitting element.

The second sub-pixel SP2 may include a second light emitting element, a second pixel circuit for driving the second light emitting element, and a second color filter CF2 that implements a color by converting the wavelength of light emitted from the second light emitting element.

The third sub-pixel SP3 may include a third light emitting element, a third pixel circuit for driving the third light emitting element, and a third color filter CF3 that implements a color by converting the wavelength of light emitted from the third light emitting element.

First electrodes 310, 320, and 330 may be patterned in the first to third sub-pixels SP1, SP2, and SP3, respectively.

One first electrode 310 may be formed in the first sub-pixel SP1, another first electrode 320 may be formed in the second sub-pixel SP2, and still another first electrode 330 may be formed in the third sub-pixel SP3.

The first electrodes 310, 320, and 330 may serve as anodes in the first to third sub-pixels SP1, SP2, and SP3 and may be electrically connected to an A electrode (e.g., a source electrode) or a B electrode (e.g., a drain electrode) of a driving thin film transistor patterned in each of the first to third sub-pixels SP1, SP2, and SP3.

The first electrodes 310, 320, and 330 may serve as liquid crystal driving electrodes for driving a liquid crystal layer.

Areas of the first electrodes 310, 320, and 330 may include emission areas EA1, EA2, and EA3.

Light may be emitted from a light emitting layer provided between the first electrodes 310, 320, and 330 and a second electrode serving as a cathode or emitted from a backlight unit.

The emitted light may be directed to the emission areas EA1, EA2, and EA3 and surrounding areas SA1, SA2, and SA3 surrounding the emission areas EA1, EA2, and EA3. The emission areas EA1, EA2, and EA3 may be non-surrounding areas NSA1, NSA2, and NSA3.

A black matrix may be disposed in the surrounding areas SA1, SA2, and SA3. The black matrix may serve to prevent light leakage due to the light emitted from the light emitting element directed to the areas (e.g., the surrounding areas SA1, SA2, and SA3) other than the emission areas EA1, EA2, and EA3.

The first sub-pixel SP1 may include the first non-surrounding area NSA1 and the first surrounding area SA1. The first non-surrounding area NSA1 may include the first emission area EA1, and the first surrounding area SA1 may be formed in a quadrangular frame structure outside the first non-surrounding area NSA1 while surrounding the first non-surrounding area NSA1, but is not limited thereto. The light emitted from the first light emitting element may be emitted through the first emission area EA1. The first surrounding area SA1 may be in contact with the first non-surrounding area NSA1 or the first emission area EA1.

The second sub-pixel SP2 may include the second non-surrounding area NSA2 and the second surrounding area SA2. The second non-surrounding area NSA2 may include the second emission area EA2, and the second surrounding area SA2 may be formed in a quadrangular frame structure outside the second non-surrounding area NSA2 while surrounding the second non-surrounding area NSA2, but is not limited thereto. The light emitted from the second light emitting element may be emitted through the second emission area EA2. The second surrounding area SA2 may be in contact with the second non-surrounding area NSA2 or the second emission area EA2.

The third sub-pixel SP3 may include the third non-surrounding area NSA3 and the third surrounding area SA3. The third non-surrounding area NSA3 may include the third emission area EA3, and the third surrounding area SA3 may be formed in a quadrangular frame structure outside the third non-surrounding area NSA3 while surrounding the third non-surrounding area NSA3, but is not limited thereto. The light emitted from the third light emitting element may be emitted through the third emission area EA3. The third surrounding area SA3 may be in contact with the third non-surrounding area NSA3 or the third emission area EA3.

The first surrounding area SA1 and the second surrounding area SA2 may be in contact with each other, and the second surrounding area SA2 and the third surrounding area SA3 may be in contact with each other.

An arrangement structure of the plurality of sub-pixels SP1, SP2, and SP3 may be changed to any of various structures known to those skilled in the art.

The first to third sub-pixels SP1, SP2, and SP3 may each implement any one color selected from the group consisting of red, green, and blue. The first to third sub-pixels SP1, SP2, and SP3 may each be implemented to have any one color selected from the group consisting of red, green, and blue in a non-overlapping manner.

Blue light may have the wavelength band of 450 nm to 495 nm, green light may have the wavelength band of 495 nm to 570 nm, and red light may have the wavelength band of 620 nm to 760 nm. However, the present specification is not specific thereto, and there may be a difference between upper and lower limits of the wavelength band for the same color depending on an operator.

For example, the first sub-pixel SP1 may implement a red color by emitting red light. For example, the second sub-pixel SP2 may implement a green color by emitting green light. For example, the third sub-pixel SP3 may implement a blue color by emitting blue light.

In addition to the first to third sub-pixels SP1, SP2, and SP3, the pixel PIX may further include a fourth sub-pixel SP4 implementing a white color (not shown).

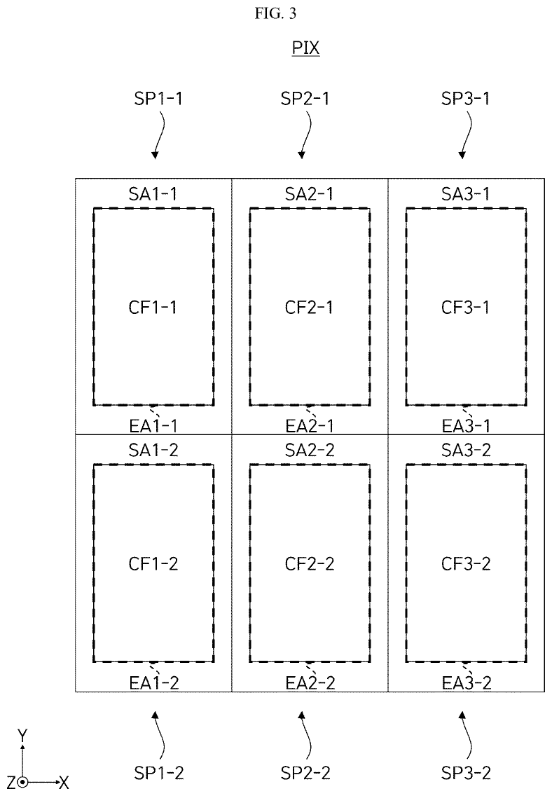

FIG. 3 is a schematic plan view showing a pixel according to another embodiment of the present specification.

Referring to FIG. 3, the pixel PIX may include a plurality of sub-pixels SP1-1, SP1-2, SP2-1, SP2-2, SP3-1, and SP3-2.

The plurality of sub-pixels may include the 1-1 sub-pixel SP1-1, the 2-1 sub-pixel SP2-1, and the 3-1 sub-pixel SP3-1 that are arranged in the first direction (e.g., the X-axis direction). The plurality of sub-pixels may include the 1-2 sub-pixel SP1-2, the 2-2 sub-pixel SP2-2, and the 3-2 sub-pixel SP3-2 that are arranged in the first direction (e.g., the X-axis direction).

The plurality of sub-pixels may include the 1-1 sub-pixel SP1-1 and the 1-2 sub-pixel SP1-2 that are arranged in a second direction (e.g., a Y direction) intersecting the first direction. The plurality of sub-pixels may include the 2-1 sub-pixel SP2-1 and the 2-2 sub-pixel SP2-2 that are arranged in the second direction (e.g., the Y direction) intersecting the first direction. The plurality of sub-pixels may include the 3-1 sub-pixel SP3-1 and the 3-2 sub-pixel SP3-2 that are arranged in the second direction (e.g., the Y direction) intersecting the first direction. However, the present specification is not limited thereto.

The plurality of sub-pixels SP1-1, SP1-2, SP2-1, SP2-2, SP3-1, and SP3-2 may each include a light emitting element, a pixel circuit for driving the light emitting element, and color filters that implement colors by converting the wavelength of light emitting from the light emitting element.

The 1-1 sub-pixel SP1-1 may include a 1-1 light emitting element, a 1-1 pixel circuit for driving the 1-1 light emitting element, and a 1-1 color filter CF1-1 that implements a color by converting the wavelength of light emitted from the 1-1 light emitting element.

The 1-2 sub-pixel SP1-2 may include a 1-2 light emitting element, a 1-2 pixel circuit for driving the 1-2 light emitting element, and a 1-2 color filter CF1-2 that implements a color by converting the wavelength of light emitted from the 1-2 light emitting element.

The 2-1 sub-pixel SP2-1 may include a 2-1 light emitting element, a 2-1 pixel circuit for driving the 2-1 light emitting element, and a 2-1 color filter CF2-1 that implements a color by converting the wavelength of light emitted from the 2-1 light emitting element.

The 2-2 sub-pixel SP2-2 may include a 2-2 light emitting element, a 2-2 pixel circuit for driving the 2-2 light emitting element, and a 2-2 color filter CF2-2 that implements a color by converting the wavelength of light emitted from the 2-2 light emitting element.

The 3-1 sub-pixel SP3-1 may include a 3-1 light emitting element, a 3-1 pixel circuit for driving the 3-1 light emitting element, and a 3-1 color filter CF3-1 that implements a color by converting the wavelength of light emitted from the 3-1 light emitting element.

The 3-2 sub-pixel SP3-2 may include a 3-2 light emitting element, a 3-2 pixel circuit for driving the 3-2 light emitting element, and a 3-2 color filter CF3-2 that implements a color by converting the wavelength of light emitted from the 3-2 light emitting element.

The display device according to the embodiment may have an improved color gamut, thereby increasing color purity and luminous efficiency.

Similar to that described with reference to FIG. 2, a first electrode (not shown) may be patterned in each of the plurality of sub-pixels SP1-1, SP1-2, SP2-1, SP2-2, SP3-1, and SP3-2.

The first electrode may serve as an anode in the first to third sub-pixels SP1, SP2, and SP3 and may be electrically connected to an A electrode (e.g., a source electrode) or a B electrode (e.g., a drain electrode) of a driving thin film transistor patterned in each of the first to third sub-pixels SP1, SP2, and SP3.

The first electrode may serve as a liquid crystal driving electrode for driving the liquid crystal layer.

An area of the first electrode may include emission areas EA1-1, EA1-2, EA2-1, EA2-2, EA3-1, and EA3-2.

Light may be emitted from a light emitting layer provided between the first electrode and the second electrode serving as a cathode or from a backlight unit. The emitted light may be directed to the emission areas EA1-1, EA1-2, EA2-1, EA2-2, EA3-1, and EA3-2 and the surrounding areas SA1-1, SA1-2, SA2-1, SA2-2, SA3-1, and SA3-2 surrounding the emission areas EA1-1, EA1-2, EA2-1, EA2-2, EA3-1, and EA3-2.

A black matrix may be disposed in the surrounding areas SA1-1, SA1-2, SA2-1, SA2-2, SA3-1, and SA3-2. The black matrix may serve to prevent light leakage due to the light emitted from the light emitting element directed to the areas (e.g., the surrounding areas SA1-1, SA1-2, SA2-1, SA2-2, SA3-1, and SA3-2) other than the emission areas EA1-1, EA1-2, EA2-1, EA1-2, EA3-1, and EA3-2.

The 1-1 sub-pixel SP1-1 may include the 1-1 emission area EA1-1 and the 1-1 surrounding area SA1-1. The 1-1 surrounding area SA1-1 may be formed in a quadrangular frame structure outside the 1-1 emission area EA1-1 while surrounding the 1-1 emission area EA1-1, but is not limited thereto. Light emitted from the 1-1 light emitting element may be emitted through the 1-1 emission area EA1-1. The 1-1 surrounding area SA1-1 may be in contact with the 1-1 emission area EA1-1.

The 1-2 sub-pixel SP1-2 may include the 1-2 emission area EA1-2 and the 1-2 surrounding area SA1-2. The 1-2 surrounding area SA1-2 may be formed in a quadrangular frame structure outside the 1-2 emission area EA1-2 while surrounding the 1-2 emission area EA1-2, but is not limited thereto. Light emitted from the 1-2 light emitting element may be emitted through the 1-2 emission area EA1-2. The 1-2 surrounding area SA1-2 may be in contact with the 1-2 emission area EA1-2.

The 2-1 sub-pixel SP2-1 may include the 2-1 emission area EA2-1 and the 2-1 surrounding area SA2-1. The 2-1 surrounding area SA2-1 may be formed in a quadrangular frame structure outside the 2-1 emission area EA2-1 while surrounding the 2-1 emission area EA2-1, but is not limited thereto. Light emitted from the 2-1 light emitting element may be emitted through the 2-1 emission area EA2-1. The 2-1 surrounding area SA2-1 may be in contact with the 2-1 emission area EA2-1.

The 2-2 sub-pixel SP2-2 may include the 2-2 emission area EA2-2 and the 2-2 surrounding area SA2-2. The 2-2 surrounding area SA2-2 may be formed in a quadrangular frame structure outside the 2-2 emission area EA2-2 while surrounding the 2-2 emission area EA2-2, but is not limited thereto. Light emitted from the 2-2 light emitting element may be emitted through the 2-2 emission area EA2-2. The 2-2 surrounding area SA2-2 may be in contact with the 2-2 emission area EA2-2.

The 3-1 sub-pixel SP3-1 may include the 3-1 emission area EA3-1 and the 3-1 surrounding area SA3-1. The 3-1 surrounding area SA3-1 may be formed in a quadrangular frame structure outside the 3-1 emission area EA3-1 while surrounding the 3-1 emission area EA3-1, but is not limited thereto. Light emitted from the 3-1 light emitting element may be emitted through the 3-1 emission area EA3-1. The 3-1 surrounding area SA3-1 may be in contact with the 3-1 emission area EA3-1.

The 3-2 sub-pixel SP3-2 may include the 3-2 emission area EA3-2 and the 3-2 surrounding area SA3-2. The 3-2 surrounding area SA3-2 may be formed in a quadrangular frame structure outside the 3-2 emission area EA3-2 while surrounding the 3-2 emission area EA3-2, but is not limited thereto. Light emitted from the 3-2 light emitting element may be emitted through the 3-2 emission area EA3-2. The 3-2 surrounding area SA3-2 may be in contact with the 3-2 emission area EA3-2.

The 1-1 surrounding area SA1-1 may be in contact with the 1-2 surrounding area SA1-2 and the 2-1 surrounding area SA2-1. The 2-2 surrounding area SA2-2 may be in contact with the 1-2 surrounding area SA1-2, the 2-1 surrounding area SA2-1, and the 3-2 surrounding area SA3-2. The 3-1 surrounding area SA3-1 may be in contact with the 2-1 surrounding area SA2-1 and the 3-2 surrounding area SA3-2.

An arrangement structure of the plurality of sub-pixels SP1-1, SP1-2, SP2-1, SP1-2, SP3-1, and SP3-2 may be changed to any of various structures known to those skilled in the art.

The 1-1 sub-pixel SP1-1 and the 1-2 sub-pixel SP1-2 may implement any one color selected from the group consisting of red, green, and blue.

The 2-1 sub-pixel SP2-1 and the 2-2 sub-pixel SP2-2 may implement any one color selected from the group consisting of red, green, and blue.

The 3-1 sub-pixel SP3-1 and the 3-2 sub-pixel SP3-2 may implement any one color selected from the group consisting of red, green, and blue.

The first sub-pixel SP1 including the 1-1 sub-pixel SP1-1 and the 1-2 sub-pixel SP1-2, the second sub-pixel SP2 including the 2-1 sub-pixel SP2-1 and the 2-2 sub-pixel SP2-2, and the third sub-pixel SP3 including 3-1 sub-pixel SP3-1 and the 3-2 sub-pixel SP3-2 may each implement any one color selected from the group consisting of red, green, and blue in an non-overlapping manner.

Blue light may have the wavelength band of 450 nm to 495 nm, green light may have the wavelength band of 495 nm to 570 nm, and red light may have the wavelength band of 620 nm to 760 nm. However, the present specification is not specific thereto, and there may be a difference between upper and lower limits of the wavelength band for the same color depending on an operator.

For example, the first sub-pixel SP1 may implement a red color by emitting red light. For example, the second sub-pixel SP2 may implement a green color by emitting green light. For example, the third sub-pixel SP3 may implement a blue color by emitting blue light.

The first sub-pixel SP1 emitting light of the same color may include the 1-1 sub-pixel SP1-1 and the 1-2 sub-pixel SP1-2 that have different peak wavelengths. The second sub-pixel SP2 emitting light of the same color may include the 2-1 sub-pixel SP2-1 and the 2-2 sub-pixel SP2-2 that have different peak wavelengths. The third sub-pixel SP3 emitting light of the same color may include the 3-1 sub-pixel SP3-1 and the 3-2 sub-pixel SP3-2 that have different peak wavelengths.

Here, the peak wavelength indicates the maximum wavelength of light (electroluminescence, EL) emitted from the sub-pixel. The wavelength at which the light emitting layer or the backlight unit emits unique light is called photoluminescence (PL). The light emitted under the influence of the thicknesses or optical characteristics of layers forming the light emitting layer or backlight units is called emittance. EL can be expressed as the product of the PL and the emittance.

For example, in the first sub-pixel SP1 emitting red light, the peak wavelength of the 1-1 sub-pixel SP1-1 may be in the range of 650 nm to 700 nm, and the peak wavelength of the 1-2 sub-pixel SP1-2 may be in the range of 600 nm to 650 nm. In the second sub-pixel SP2 emitting green light, the peak wavelength of the 2-1 sub-pixel SP2-1 may be in the range of 500 nm to 520 nm, and the peak wavelength of the 2-2 sub-pixel SP2-2 may be in the range of 520 nm to 550 nm. In the third sub-pixel SP3 emitting blue light, the peak wavelength of the 3-1 sub-pixel SP3-1 may be in the range of 400 nm to 450 nm, and the peak wavelength of the 3-2 sub-pixel SP3-2 may be in the range of 450 nm to 500 nm.

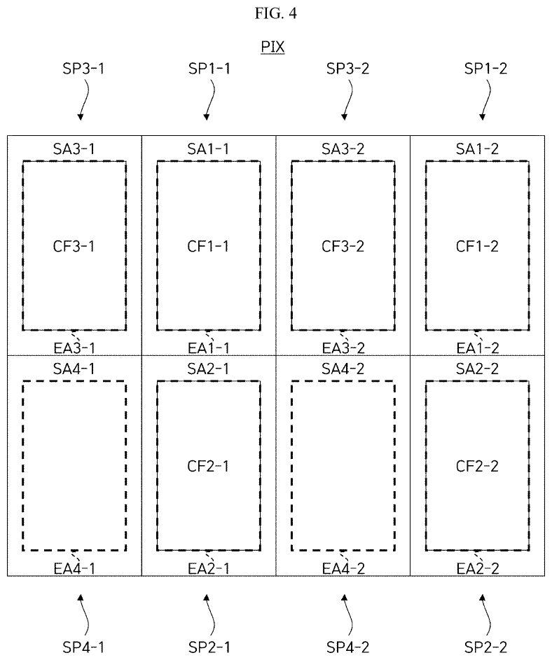

FIG. 4 is a schematic plan view showing a pixel according to still another embodiment of the present specification.

Referring to FIG. 4, the pixel PIX may include a plurality of sub-pixels SP1-1, SP1-2, SP2-1, SP2-2, SP3-1, SP3-2, SP4-1, and SP4-2.

The plurality of sub-pixels may include the 1-1 sub-pixel SP1-1, the 1-2 sub-pixel SP1-2, the 3-1 sub-pixel SP3-1, and the 3-2 sub-pixel SP3-2 that are arranged in the first direction (e.g., the X-axis direction). The plurality of sub-pixels may include the 2-1 sub-pixel SP2-1, the 2-2 sub-pixel SP2-2, the 4-1 sub-pixel SP4-1, and the 4-2 sub-pixel SP4-2 that are arranged in the first direction (e.g., the X-axis direction).

The plurality of sub-pixels may include the 1-1 sub-pixel SP1-1 and the 2-1 sub-pixel SP2-1 that are arranged in the second direction (e.g., the Y direction) intersecting the first direction. The plurality of sub-pixels may include the 3-1 sub-pixel SP3-1 and the 4-1 sub-pixel SP4-1 that are arranged in the second direction (e.g., the Y direction) intersecting the first direction. The plurality of sub-pixels may include the 1-2 sub-pixel SP1-2 and the 2-2 sub-pixel SP2-2 that are arranged in the second direction (e.g., the Y direction) intersecting the first direction. The plurality of sub-pixels may include the 3-2 sub-pixel SP3-2 and the 4-2 sub-pixel SP4-2 that are arranged in the second direction (e.g., the Y direction) intersecting the first direction. However, the present specification is not limited thereto.

The plurality of sub-pixels SP1-1, SP1-2, SP2-1, SP2-2, SP3-1, and SP3-2 may each include a light emitting element, a pixel circuit for driving the light emitting element, and color filters that implement colors by converting the wavelength of light emitting from the light emitting element.

The 4-1 sub-pixel SP4-1 and the 4-2 sub-pixel SP4-2 may each include a light emitting element and a pixel circuit for driving the light emitting element.

The 1-1 sub-pixel SP1-1 may include the 1-1 light emitting element, the 1-1 pixel circuit for driving the 1-1 light emitting element, and the 1-1 color filter CF1-1 that implements a color by converting the wavelength of light emitted from the 1-1 light emitting element.

The 1-2 sub-pixel SP1-2 may include the 1-2 light emitting element, the 1-2 pixel circuit for driving the 1-2 light emitting element, and a 1-2 color filter CF1-2 that implements a color by converting the wavelength of light emitted from the 1-2 light emitting element.

The 2-1 sub-pixel SP2-1 may include the 2-1 light emitting element, the 2-1 pixel circuit for driving the 2-1 light emitting element, and the 2-1 color filter CF2-1 that implements a color by converting the wavelength of light emitted from the 2-1 light emitting element.

The 2-2 sub-pixel SP2-2 may include the 2-2 light emitting element, the 2-2 pixel circuit for driving the 2-2 light emitting element, and the 2-2 color filter CF2-2 that implements a color by converting the wavelength of light emitted from the 2-2 light emitting element.

The 3-1 sub-pixel SP3-1 may include the 3-1 light emitting element, the 3-1 pixel circuit for driving the 3-1 light emitting element, and the 3-1 color filter CF3-1 that implements a color by converting the wavelength of light emitted from the 3-1 light emitting element.

The 3-2 sub-pixel SP3-2 may include the 3-2 light emitting element, the 3-2 pixel circuit for driving the 3-2 light emitting element, and the 3-2 color filter CF3-2 that implements a color by converting the wavelength of light emitted from the 3-2 light emitting element.

The 4-1 sub-pixel SP4-1 may include the 4-1 light emitting element and the 4-1 pixel circuit for driving the 4-1 light emitting element.

The 4-2 sub-pixel SP4-2 may include the 4-2 light emitting element and the 4-2 pixel circuit for driving the 4-2 light emitting element.

Similar to that described with reference to FIG. 2, the first electrode (not shown) may be patterned in each of the plurality of sub-pixels SP1-1, SP1-2, SP2-1, SP2-2, SP3-1, SP3-2, SP4-1, and SP4-2.

The first electrode may serve as an anode in the first to fourth sub-pixels SP1, SP2, SP3, and SP4 and may be electrically connected to an A electrode (e.g., a source electrode) or a B electrode (e.g., a drain electrode) of a driving thin film transistor patterned in each of the first to fourth sub-pixels SP1, SP2, SP3, and SP4.

The first electrode may serve as a liquid crystal driving electrode for driving the liquid crystal layer.

An area of the first electrode may include emission areas EA1-1, EA1-2, EA2-1, EA2-2, EA3-1, EA3-2, EA4-1, and EA4-2.

Light may be emitted from a light emitting layer provided between the first electrode and the second electrode serving as a cathode or from a backlight unit. The emitted light may be directed to the emission areas EA1-1, EA1-2, EA2-1, EA2-2, EA3-1, EA3-2, EA4-1, and EA4-2 and the surrounding areas SA1-1, SA1-2, SA2-1, SA2-2, SA3-1, SA3-2, SA4-1, and SA4-2 surrounding the emission areas EA1-1, EA1-2, EA2-1, EA2-2, EA3-1, EA3-2, EA4-1, and EA4-2.

A black matrix may be disposed in the surrounding areas SA1-1, SA1-2, SA2-1, SA2-2, SA3-1, SA3-2, SA4-1, and SA4-2. The black matrix may serve to prevent light leakage due to the light emitted from the light emitting element directed to the areas (e.g., the surrounding areas SA1-1, SA1-2, SA2-1, SA2-2, SA3-1, SA3-2, SA4-1, and SA4-2) other than the emission areas EA1-1, EA1-2, EA2-1, EA2-2, EA3-1, EA3-2, EA4-1, and EA4-2.

The 1-1 sub-pixel SP1-1 may include the 1-1 emission area EA1-1 and the 1-1 surrounding area SA1-1. The 1-1 surrounding area SA1-1 may be formed in a quadrangular frame structure outside the 1-1 emission area EA1-1 while surrounding the 1-1 emission area EA1-1, but is not limited thereto. Light emitted from the 1-1 light emitting element may be emitted through the 1-1 emission area EA1-1. The 1-1 surrounding area SA1-1 may be in contact with the 1-1 emission area EA1-1.

The 1-2 sub-pixel SP1-2 may include the 1-2 emission area EA1-2 and the 1-2 surrounding area SA1-2. The 1-2 surrounding area SA1-2 may be formed in a quadrangular frame structure outside the 1-2 emission area EA1-2 while surrounding the 1-2 emission area EA1-2, but is not limited thereto. Light emitted from the 1-2 light emitting element may be emitted through the 1-2 emission area EA1-2. The 1-2 surrounding area SA1-2 may be in contact with the 1-2 emission area EA1-2.

The 2-1 sub-pixel SP2-1 may include the 2-1 emission area EA2-1 and the 2-1 surrounding area SA2-1. The 2-1 surrounding area SA2-1 may be formed in a quadrangular frame structure outside the 2-1 emission area EA2-1 while surrounding the 2-1 emission area EA2-1, but is not limited thereto. Light emitted from the 2-1 light emitting element may be emitted through the 2-1 emission area EA2-1. The 2-1 surrounding area SA2-1 may be in contact with the 2-1 emission area EA2-1.

The 2-2 sub-pixel SP2-2 may include the 2-2 emission area EA2-2 and the 2-2 surrounding area SA2-2. The 2-2 surrounding area SA2-2 may be formed in a quadrangular frame structure outside the 2-2 emission area EA2-2 while surrounding the 2-2 emission area EA2-2, but is not limited thereto. Light emitted from the 2-2 light emitting element may be emitted through the 2-2 emission area EA2-2. The 2-2 surrounding area SA2-2 may be in contact with the 2-2 emission area EA2-2.

The 3-1 sub-pixel SP3-1 may include the 3-1 emission area EA3-1 and the 3-1 surrounding area SA3-1. The 3-1 surrounding area SA3-1 may be formed in a quadrangular frame structure outside the 3-1 emission area EA3-1 while surrounding the 3-1 emission area EA3-1, but is not limited thereto. Light emitted from the 3-1 light emitting element may be emitted through the 3-1 emission area EA3-1. The 3-1 surrounding area SA3-1 may be in contact with the 3-1 emission area EA3-1.

The 3-2 sub-pixel SP3-2 may include the 3-2 emission area EA3-2 and the 3-2 surrounding area SA3-2. The 3-2 surrounding area SA3-2 may be formed in a quadrangular frame structure outside the 3-2 emission area EA3-2 while surrounding the 3-2 emission area EA3-2, but is not limited thereto. Light emitted from the 3-2 light emitting element may be emitted through the 3-2 emission area EA3-2. The 3-2 surrounding area SA3-2 may be in contact with the 3-2 emission area EA3-2.

The 4-1 sub-pixel SP4-1 may include the 4-1 emission area EA4-1 and the 4-1 surrounding area SA4-1. The 4-1 surrounding area SA4-1 may be formed in a quadrangular frame structure outside the 4-1 emission area EA4-1 while surrounding the 4-1 emission area EA4-1, but is not limited thereto. Light emitted from the 4-1 light emitting element may be emitted through the 4-1 emission area EA4-1. The 4-1 surrounding area SA4-1 may be in contact with the 4-1 emission area EA4-1.

The 4-2 sub-pixel SP4-2 may include the 4-2 emission area EA4-2 and the 4-2 surrounding area SA4-2. The 4-2 surrounding area SA4-2 may be formed in a quadrangular frame structure outside the 4-2 emission area EA4-2 while surrounding the 4-2 emission area EA4-2, but is not limited thereto. Light emitted from the 4-2 light emitting element may be emitted through the 4-2 emission area EA4-2. The 4-2 surrounding area SA4-2 may be in contact with the 4-2 emission area EA4-2.

The 3-1 surrounding area SA3-1 may be in contact with the 1-1 surrounding area SA1-1 and the 4-1 surrounding area SA4-1. The 2-1 surrounding area SA2-1 may be in contact with the 4-1 surrounding area SA4-1, the 1-1 surrounding area SA1-1, and the 4-2 surrounding area SA4-2. The 3-2 surrounding area SA3-2 may be in contact with the 1-1 surrounding area SA1-1, the 4-2 surrounding area SA4-2, and the 1-2 surrounding area SA1-2. The 2-2 surrounding area SA2-2 may be in contact with the 1-2 surrounding area SA1-2 and the 4-2 surrounding area SA4-2.

An arrangement structure of the plurality of sub-pixels SP1-1, SP1-2, SP2-1, SP2-2, SP3-1, SP3-2, SP4-1, and SP4-2 may be changed to any of various structures known to those skilled in the art.

The 1-1 sub-pixel SP1-1 and the 1-2 sub-pixel SP1-2 may implement any one color selected from the group consisting of red, green, blue, and white. The 1-1 sub-pixel SP1-1 and the 1-2 sub-pixel SP1-2 may not include a color filter when implementing a white color.

The 2-1 sub-pixel SP2-1 and the 2-2 sub-pixel SP2-2 may implement any one color selected from the group consisting of red, green, blue, and white. The 2-1 sub-pixel SP2-1 and the 2-2 sub-pixel SP2-2 may not include a color filter when implementing a white color.

The 3-1 sub-pixel SP3-1 and the 3-2 sub-pixel SP3-2 may implement any one color selected from the group consisting of red, green, blue, and white. The 3-1 sub-pixel SP3-1 and the 3-2 sub-pixel SP3-2 may not include a color filter when implementing a white color.

The 4-1 sub-pixel SP4-1 and the 4-2 sub-pixel SP4-2 may implement any one color selected from the group consisting of red, green, blue, and white. The 4-1 sub-pixel SP4-1 and the 4-2 sub-pixel SP4-2 may include a color filter when implementing any one color of red, green, and blue.

The first sub-pixel SP1 including the 1-1 sub-pixel SP1-1 and the 1-2 sub-pixel SP1-2, the second sub-pixel SP2 including the 2-1 sub-pixel SP2-1 and the 2-2 sub-pixel SP2-2, the third sub-pixel SP3 including the 3-1 sub-pixel SP3-1 and the 3-2 sub-pixel SP3-2, and the fourth sub-pixel SP4 including 4-1 sub-pixel SP4-1 and the 4-2 sub-pixel SP4-2 may each implement any one color selected from the group consisting of red, green, blue, and white in an non-overlapping manner.

Blue light may have the wavelength band of 450 nm to 495 nm, green light may have the wavelength band of 495 nm to 570 nm, and red light may have the wavelength band of 620 nm to 760 nm. However, the present specification is not specific thereto, and there may be a difference between upper and lower limits of the wavelength band for the same color depending on an operator.

For example, the first sub-pixel SP1 may implement a red color by emitting red light. For example, the second sub-pixel SP2 may implement a green color by emitting green light. For example, the third sub-pixel SP3 may implement a blue color by emitting blue light.

The first sub-pixel SP1 emitting light of the same color may include the 1-1 sub-pixel SP1-1 and the 1-2 sub-pixel SP1-2 that have different peak wavelengths. The second sub-pixel SP2 emitting light of the same color may include the 2-1 sub-pixel SP2-1 and the 2-2 sub-pixel SP2-2 that have different peak wavelengths. The third sub-pixel SP3 emitting light of the same color may include the 3-1 sub-pixel SP3-1 and the 3-3 sub-pixel SP3-2 that have different peak wavelengths. However, when white light is implemented by any one of the first to third sub-pixels SP1, SP2, and SP3, the peak wavelengths may not be different. White has no corresponding wavelength.

The fourth sub-pixel SP4 emitting light of the same color may include the 4-1 sub-pixel SP4-1 and the 4-2 sub-pixel SP4-2. However, when any one of red, green, and blue light is implemented by the fourth sub-pixel SP4, the peak wavelengths of the 4-1 sub-pixel SP4-1 and the 4-2 sub-pixel SP4-2 may be different.

For example, in the first sub-pixel SP1 emitting red light, the peak wavelength of the 1-1 sub-pixel SP1-1 may be in the range of 650 nm to 700 nm, and the peak wavelength of the 1-2 sub-pixel SP1-2 may be in the range of 600 nm to 650 nm. In the second sub-pixel SP2 emitting green light, the peak wavelength of the 2-1 sub-pixel SP2-1 may be in the range of 500 nm to 520 nm, and the peak wavelength of the 2-2 sub-pixel SP2-2 may be in the range of 520 nm to 550 nm. In the third sub-pixel SP3 emitting blue light, the peak wavelength of the 3-1 sub-pixel SP3-1 may be in the range of 400 nm to 450 nm, and the peak wavelength of the 3-2 sub-pixel SP3-2 may be in the range of 450 nm to 500 nm. The peak wavelengths of the 4-1 sub-pixel SP4-1 and the 4-2 sub-pixel SP4-2 may not be present.

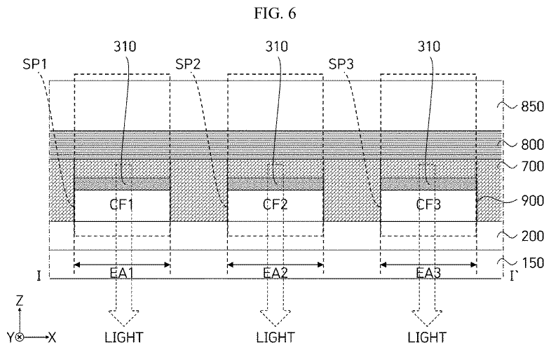

FIG. 5 is a schematic cross-sectional view showing one example of a cross-sectional structure of a pixel along line I-I of FIG. 2 in a top emission type display panel. FIG. 6 is a schematic cross-sectional view showing one example of a cross-sectional structure of a pixel along line I-I of FIG. 2 in a bottom emission type display panel.

Referring to FIGS. 5 and 6, the display panel may include a substrate 150, a circuit element layer 200, a first electrode 310, a light emitting layer 700, a second electrode 800, an encapsulation layer 850, and a color filter layer 900.

The substrate 150 may be manufactured based on a glass, plastic, or silicon wafer. The substrate 150 may be construed as a backplane.

Trenches recessed concavely may be disposed between adjacent sub-pixels SP1, SP2, and SP3. The trench can block a current flowing between neighboring sub-pixels. The trench can block a leakage current flowing into the sub-pixels by forming a long current path between the adjacent sub-pixels SP1, SP2, and SP3.

The circuit element layer 200, the light emitting layer 700, and the encapsulation layer 850 may be sequentially stacked on the substrate 150.

The circuit element layer 200 may include a pixel circuit for driving the light emitting elements of the sub-pixels SP1, SP2, and SP3 according to the pixel data of the input images. The circuit element layer 200 may further include a gate driving circuit for supplying the gate signal to the pixel circuit. The pixel circuit may include a driving transistor for supplying a current to the light emitting element according to a voltage between the gate and the source, a switching transistor for applying the data voltage of the pixel data to the gate or source of the driving transistor, a storage capacitor for maintaining the voltage between the gate and source of the driving transistor, a plurality of insulating layers for insulating metal patterns of the circuit elements, etc.

The light emitting layer 700 may include a light emitting element disposed in each of the sub-pixels SP1, SP2, and SP3 and driven by the pixel circuit. The light emitting element may be a white light emitting element commonly disposed in the sub-pixels SP1, SP2, and SP3 to generate white light. In another embodiment, a red light emitting element that emits red light may be disposed in the first sub-pixel SP1, a green light emitting element that emits green light may be disposed in the second sub-pixel SP2, and a blue light emitting element that emits blue light may be disposed in the third sub-pixel SP3.

When a white light emitting element is disposed in the sub-pixels SP1, SP2, and SP3, the color filters CF1, CF2, and CF3 that selectively transmit light with the wavelength of each color may be disposed. The color filters CF1, CF2, and CF3 may implement colors by converting the wavelength of light emitted from the white light emitting element.

The light emitting elements of the light emitting layer 700 may be covered by multiple protective layers including an organic layer and an inorganic layer.

The light emitting element may be implemented as an organic light emitting element or an inorganic light emitting element. For example, the light emitting element may be implemented as an OLED or an inorganic LED. The light emitting element may include the first electrode 310, the second electrode 800, and the light emitting layer 700 formed between the electrodes 310 and 800. The first electrode 310 may be an anode of the light emitting element separated for each sub-pixel. The second electrode 800 may be a common electrode shared by the sub-pixels. The second electrode 800 may be a cathode of the light emitting element.

The encapsulation layer 850 may cover the light emitting layer 700 to seal the circuit element layer 200 and the light emitting layer 700. The encapsulation layer 850 may have a multi-insulating film structure in which organic films and inorganic films are stacked alternately. The inorganic film can block permeation of moisture or oxygen. The organic film may planarize a surface of the inorganic film. When the organic film and the inorganic film are stacked in multiple layers, a movement path of moisture or oxygen may be longer than that of a single layer, thereby effectively blocking the permeation of moisture and oxygen affecting the light emitting layer 700.

The display panel may have a top emission type as shown in FIG. 5 or a bottom emission type as shown in FIG. 6.

In the top emission type display panel, light LIGHT emitted from the light emitting layer 700 may be emitted to the outside after passing through the second electrode 800, the encapsulation layer 850, and the color filters CF1, CF2, and CF3. In the top emission type display panel, the first electrode 310 may serve as a reflective layer to increase light efficiency, and the second electrode 800 may be implemented as a transparent or translucent electrode. In the top emission type display panel, a distance between the first electrode 310 and the second electrode 800 may be set differently for each color of the sub-pixels SP1, SP2, and SP3 to obtain the micro-cavity effect.

In the bottom emission type display panel, light LIGHT emitted from the light emitting layer 700 may be emitted to the outside after passing through the first electrode 310, the circuit element layer 200, the color filters CF1, CF2, and CF3, and the substrate 150. In the bottom emission type display panel, the second electrode 800 may serve as a reflective layer to increase light efficiency, and the first electrode 310 may be implemented as a transparent or translucent electrode.

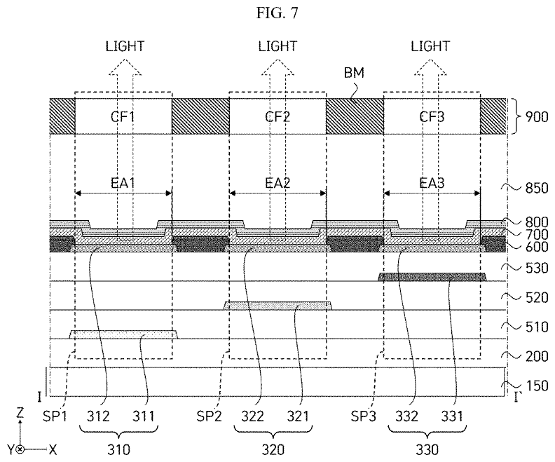

FIG. 7 is a cross-sectional view showing another example of the cross-sectional structure of the pixel along line I-I of FIG. 2.

Referring to FIGS. 7, the display panel may include the substrate 150, the circuit element layer 200, the first electrodes 310, 320, and 330, insulating layers 510, 520, and 530, a bank 600, the light emitting layer 700, the second electrode 800, the encapsulation layer 850, and the color filter layer 900.

The plurality of sub-pixels SP1, SP2, and SP3 may be formed on the substrate 150. Each of the plurality of sub-pixels SP1, SP2, and SP3 may be provided with the emission areas EA1, EA2, and EA3. The first emission area EA1 may be provided in the first sub-pixel SP1, the second emission area EA2 may be provided in the second sub-pixel SP2, and the third emission area EA3 may be provided in the third sub-pixel SP3.

The plurality of emission areas EA1, EA2, and EA3 may be defined by the bank 600. Exposed areas that are not covered by the bank 600 may become the plurality of emission areas EA1, EA2, and EA3.

The first electrodes 310, 320, and 330 may be patterned for each sub-pixel SP1, SP2, and SP3. One first electrode 310 may be formed in the first sub-pixel SP1, another first electrode 320 may be formed in the second sub-pixel SP2, and still another first electrode 320 may be formed in the third sub-pixel SP3. The first electrodes 310, 320, and 330 may each serve as an anode (or a positive electrode).

The first electrode 310 of the first sub-pixel SP1 may extend together with the first emission area EA1, and an exposed portion of the first electrode 310 that is not covered by the bank 600 may become the first emission area EA1.

The first electrode 320 of the second sub-pixel SP2 may extend together with the second emission area EA2, and an exposed portion of the first electrode 320 that is not covered by the bank 600 may become the second emission area EA2.

The first electrode 330 of the third sub-pixel SP3 may extend together with the third emission area EA3, and an exposed portion of the first electrode 330 that is not covered by the bank 600 may become the third emission area EA3.

The substrate 150 may be made of a glass or plastic, but is not necessarily limited thereto, and may be made of a semiconductor material, such as a silicon wafer.

The substrate 150 may be made of a transparent material or an opaque material. The first sub-pixel SP1, the second sub-pixel SP2, and the third sub-pixel SP3 may be provided on the substrate 150.

Although the first sub-pixel SP1 may emit red light, the second sub-pixel SP2 may emit green light, and the third sub-pixel SP3 may emit blue light, the present invention is not necessarily limited thereto. For example, the arrangement order of the sub-pixels SP1, SP2, and SP3 may be changed in any of various ways.

The display device may operate in the top emission manner in which the emitted light is emitted upward (e.g., the Z-axis direction), and as a material of the substrate 150, an opaque material as well as a transparent material may be used. However, the present specification is not limited thereto, and the display device may be operated in a bottom emission manner, and the configuration of the present invention accordingly may be appropriately modified depending on an operator.

The circuit element layer 200 may be formed on the substrate 150. The circuit element layer 200 may be provided with circuit elements including various signal lines, thin film transistors, capacitors, and the like for each of the sub-pixels SP1, SP2, and SP3. The signal lines may include gate lines, data lines, power lines, and reference lines. The thin film transistors may include a switching thin film transistor, a driving thin film transistor, and a sensing thin film transistor.

The switching thin film transistor may be switched according to a gate signal supplied to the gate line to supply a data voltage supplied from the data line to the driving thin film transistor.

The driving thin film transistor may be switched according to the data voltage supplied from the switching thin film transistor to generate a data current from the power supplied from the power line and supply the data current to the first electrodes 310, 320, and 330.

The sensing thin film transistor may serve to sense a threshold voltage deviation of the driving thin film transistors, which causes the degradation of image quality. Specifically, the current of the driving thin film transistor may be supplied to the reference line in response to a sensing control signal supplied from the gate line or a separate sensing line.

The capacitor may serve to maintain the data voltage supplied to the driving thin film transistor for one frame. The capacitor may be connected to a gate electrode and source electrode of the driving thin film transistor.

The first electrodes 310, 320, and 330 may be patterned for each of the sub-pixels SP1, SP2, and SP3 on the circuit element layer 200. One first electrode 310 may be formed in the first sub-pixel SP1, another first electrode 320 may be formed in the second sub-pixel SP2, and still another first electrode 330 may be formed in the third sub-pixel SP3.

The first electrodes 310, 320, and 330 may be connected to a driving thin film transistor 250 provided on the circuit element layer 200. Specifically, the first electrodes 310, 320, and 330 may be connected to a source electrode of the driving thin film transistor 250.

The first electrode 310 provided in the first sub-pixel SP1 may include a first lower electrode 311 and a first upper electrode 312.

The first lower electrode 311 may be connected to the driving thin film transistor of the circuit element layer 200 in an area including the first sub-pixel SP1. As one embodiment, the first lower electrode 311 may be connected to the driving thin film transistor through a contact hole (not shown).

In the first sub-pixel SP1, the first lower electrode 311 may be directly connected to the driving thin film transistor provided on the circuit element layer 200, and the first upper electrode 312 may be connected to the first lower electrode 311. Specifically, the first upper electrode 312 may be connected to the first lower electrode 311 through a contact electrode (not shown).

In the first emission area EA1 of the first sub-pixel SP1, a first insulating layer 510, a second insulating layer 520, and a third insulating layer 530 may be disposed between the first lower electrode 311 and the first upper electrode 312.

The first electrode 320 provided in the second sub-pixel SP2 may include a second lower electrode 321 and a second upper electrode 322.

The second lower electrode 321 may be connected to another driving thin film transistor of the circuit element layer 200 in an area including the second sub-pixel SP2. The second lower electrode 321 may be connected to the driving thin film transistor through a contact hole (not shown).

In the second sub-pixel SP2, the second lower electrode 321 may be directly connected to the driving thin film transistor provided on the circuit element layer 200, and the second upper electrode 322 may be connected to the second lower electrode 321. Specifically, the second upper electrode 322 may be connected to the second lower electrode 321 through a contact electrode (not shown).

In the second emission area EA2 of the second sub-pixel SP2, a second insulating layer 520 and a third insulating layer 530 may be disposed between the second lower electrode 321 and the second upper electrode 322.

The first electrode 330 provided in the third sub-pixel SP3 may include a third lower electrode 331 and a third upper electrode 332.

The third lower electrode 331 may be connected to another driving thin film transistor of the circuit element layer 200 in an area including the third sub-pixel SP3. As another embodiment, the third lower electrode 331 may be connected to the driving thin film transistor through a contact hole (not shown).

In the third sub-pixel SP3, the third lower electrode 331 may be directly connected to the driving thin film transistor provided on the circuit element layer 200, and the third upper electrode 332 may be connected to the third lower electrode 331. Specifically, the third upper electrode 332 may be connected to the third lower electrode 331 through a contact electrode (not shown).

In the third emission area EA3 of the third sub-pixel SP3, a third insulating layer 530 may be disposed between the third lower electrode 331 and the third upper electrode 332.

A distance between the first lower electrode 311 and the first upper electrode 312 in the first sub-pixel SP1, a distance between the second lower electrode 321 and the second upper electrode 322 in the second sub-pixel SP2, and a distance between the third lower electrode 331 and the third upper electrode 332 in the third sub-pixel SP3 are all different, and thus it is possible to achieve the micro-cavity effect. Detailed description thereof will be made below.

The first insulating layer 510 may be disposed on the circuit element layer 200. The first insulating layer 510 may be formed entirely on the areas of the plurality of sub-pixels SP1, SP2, and SP3, and the first insulating layer 510 formed on the first sub-pixel SP1, the first insulating layer 510 formed on the second sub-pixel SP2, and the first insulating layer 510 formed on the third sub-pixel SP3 may be connected.

The second insulating layer 520 may be disposed on the first insulating layer 510. The second insulating layer 520 may be formed entirely on the areas of the plurality of sub-pixels SP1, SP2, and SP3, and the second insulating layer 520 formed on the first sub-pixel SP1, the second insulating layer 520 formed on the second sub-pixel SP2, and the second insulating layer 520 formed on the third sub-pixel SP3 may be connected.

The third insulating layer 530 may be disposed on the second insulating layer 520. The third insulating layer 530 may be formed entirely on the area of the plurality of sub-pixels SP1, SP2, and SP3, and the third insulating layer 530 formed on the first sub-pixel SP1, the third insulating layer 530 formed on the second sub-pixel SP2, and the third insulating layer 530 formed on the third sub-pixel SP3 may be connected.

The display device may be operated in the top emission manner. To this end, the first electrodes 310, 320, and 330 may be formed to allow the light emitted from the light emitting layer 700 to be reflected toward a front surface of the display device (e.g., in the Z-axis direction). To this end, the first to third lower electrodes 311, 321, and 331 positioned at rear surfaces (e.g., lower sides) of the first electrodes 310, 320, and 330 having a double-layer structure are reflective electrodes, and the first to third upper electrodes 312, 322, and 332 positioned on front surfaces (e.g., upper sides) of the first electrodes 310, 320, and 330 may be formed as transparent electrodes or translucent electrodes. In this case, the first to third upper electrodes 312, 322, and 332 may serve as anodes (or positive electrodes) of the first to third sub-pixels SP1, SP2, and SP3, respectively.

The reflective electrode may be an electrode that reflects incident light, the transparent electrode may be an electrode that transmits incident light, and the translucent electrode may be an electrode that transmits some of the incident light and reflects the rest. In terms of transparency, the transparency can be excellent in the order of the reflective electrode, the translucent electrode, and the transparent electrode. In terms of reflectivity, the reflectivity can be excellent in the order of the transparent electrode, the translucent electrode, and the reflective electrode.

The first upper electrode 312 of the first sub-pixel SP1, the second upper electrode 322 of the second sub-pixel SP2, and the third upper electrode 332 of the third sub-pixel SP3 may be patterned using the same material and the same process.

When the first to third lower electrodes 311, 321, and 331 are formed as the reflective electrodes and the first to third upper electrodes 312, 322, and 332 are formed as the transparent electrodes, some of the light emitted from the light emitting layer 700 may pass through the first to third upper electrodes 312, 322, and 332 after reflected from the first to third lower electrodes 311, 321, and 331, and travel upward.

When the first to third lower electrodes 311, 321, and 331 are formed as the reflective electrodes and the first to third upper electrodes 312, 322, and 332 are formed as the translucent electrodes, some of the light emitted from the light emitting layer 700 may pass through the first to third upper electrodes 312, 322, and 332 and travel upward.

Some of the light emitted from the light emitting layer 700 may be reflected from the first to third upper electrodes 312, 322, and 332, re-reflected from the first to third lower electrodes 311, 321, and 331, and as a result, may travel upward.

Specifically, another part of the light reflected from the first to third upper electrodes 312, 322, and 332 may be reflected from the first to third lower electrodes 311, 321, and 331. In this case, some of the light reflected from the first to third lower electrodes 311, 321, and 331 may pass through the first to third upper electrodes 312, 322, and 332 and travel upward, and another part of the light reflected from the first to third lower electrodes 311, 321, and 331 may be reflected from the first to third upper electrodes 312, 322, and 332 and travel downward. This may be re-reflected from the first to third lower electrodes 311, 321, and 331, and the above-described processes may be repeated.

As described above, light may be amplified as reflection and re-reflection are repeated between the first to third lower electrodes 311, 321, and 331 and the first to third upper electrodes 312, 322, and 332, thereby increasing the light efficiency of the display device according to the embodiment.

When distances between the first to third lower electrodes 311, 321, and 331 and the first to third upper electrodes 312, 322, and 332 are integer multiple of a half wavelength (2/2) of the light emitted from each of the sub-pixels SP1, SP2, and SP3, constructive interference may occur, thereby further amplifying the light. Therefore, when the above-described reflection and re-reflection process is repeated, the degree to which light is amplified may continuously increase, thereby increasing the external extraction efficiency of light. Such a characteristic is called the micro-cavity (resonance) effect.

A first distance between the first lower electrode 311 and the first upper electrode 312 in the first sub-pixel SP1, a second distance between the second lower electrode 321 and the second upper electrode 322 in the second sub-pixel SP2, and a third distance between the third lower electrode 331 and the third upper electrode 332 in the third sub-pixel SP3 may all be configured differently. Therefore, the micro-cavity effect can be achieved in each of the sub-pixels SP1, SP2, and SP3.

For example, although the first distance in the first sub-pixel SP1 that emits red light in a long wavelength band may be configured longest, and the third distance in the third sub-pixel SP3 that emits blue light in a short wavelength band may be configured shortest, the present invention is not necessarily limited thereto.

In addition, distances between the first to third upper electrodes 312, 322, and 332 and the second electrode 800 in each of the plurality of sub-pixels SP1, SP2, and SP3 may all be the same, and the first to third upper electrodes 312, 322, and 332 may be formed at the same height on the third insulating layer 530. Therefore, since a lower surface of the light emitting layer 700 formed on the first to third upper electrodes 312, 322, and 332 has an overall uniform height, it is possible to improve the profile of the light emitting layer 700 compared to a case in which the first to third upper electrodes 312, 322, and 332 are formed at different heights. Even in various embodiments below, although the distances between the first to third upper electrodes 312, 322, and 332 and the second electrode 800 in each of the plurality of sub-pixels SP1, SP2, and SP3 are all formed identically, and the first to third upper electrodes 312, 322, and 332 may be formed at the same height on the third insulating layer 530, the present specification is not necessarily limited thereto.

The bank 600 may be formed to cover ends of the first to third upper electrodes 312, 322, and 332 of the first electrodes 310, 320, and 330 on the third insulating layer 530. Therefore, it is possible to solve a problem that a current is concentrated on the ends of the first to third upper electrodes 312, 322, and 332, thereby degrading luminous efficiency.

The bank 600 may be formed in a matrix structure at the boundary between the plurality of sub-pixels SP1, SP2, and SP3 and may define the emission areas EA1, EA2, and EA3 in each of the plurality of sub-pixels SP1, SP2, and SP3. The exposed areas of the first to third upper electrodes 312, 322, and 332 on which the bank 600 is not formed in each of the sub-pixels SP1, SP2, and SP3 may become the emission areas EA1, EA2, and EA3.

A portion of the bank 600 may be formed to overlap each of the plurality of first electrodes 310, 320, and 330 extending together with the plurality of emission areas EA1, EA2, and EA3 in the planar direction of the display panel.

The bank 600 may be formed of a relatively thin inorganic insulating film, but may be formed of a relatively thick organic insulating film.

The light emitting layer 700 may be formed on the first to third upper electrodes 312, 322, and 332 of the first electrodes 310, 320, and 330. The light emitting layer 700 may also be formed on the bank 600. The light emitting layer 700 may also be formed in each of the sub-pixels SP1, SP2, and SP3 and in boundary areas therebetween.

The light emitting layer 700 may be formed to emit white (W) light. To this end, the light emitting layer 700 may include a plurality of stacks that emit light of different colors. For example, the light emitting layer 700 may include a first stack that emits blue light, a second stack that emits yellow-green light, and a charge generation layer CGL provided between the first stack and the second stack. As another example, the light emitting layer 700 may include the first stack that emits blue light, the second stack that emits green light, the third stack that emits red light, a first charge generation layer provided between the first stack and the second stack, and a second charge generation layer provided between the second stack and the third stack.

Each of the stacks may include a hole injection layer (HIL), a hole transport layer (HTL), an emission layer (EML), an electron transport layer (ETL), an electron transport layer (ETL), and an electron injection layer (EIL). The configuration of the light emitting layer 700 may be modified into various forms known in the art to which the present invention pertains.

The second electrode 800 may be formed on the light emitting layer 700. The second electrode 800 may serve as a cathode (or a negative electrode) of the display device. Like the light emitting layer 700, the second electrode 800 may be formed in each of the sub-pixels SP1, SP2, and SP3 and the boundary areas therebetween. The second electrode 800 may be formed on the bank 600.

The display device may be driven in the top emission manner. To transmit light emitted from the light emitting layer 700 toward the front surface (e.g., an upper portion) of the display device, the second electrode 800 may be made a transparent conductive material.

Since the second electrode 800 may be formed as a translucent electrode, it is possible to achieve the micro-cavity effect for each of the sub-pixels SP1, SP2, and SP3. When the second electrode 800 is a translucent electrode, the reflection and re-reflection of light may be repeated between the second electrode 800 and the first to third lower electrodes 311, 321, and 331 of the first electrodes 310, 320, and 330, thereby achieving the micro-cavity effect. Alternatively, the reflection and re-reflection of light may be repeated between the second electrode 800 and the first to third upper electrodes 312, 322, and 332 of the first electrodes 310, 320, and 330, thereby achieving the micro-cavity effect.

The encapsulation layer 850 may be formed on the second electrode 800 to prevent external moisture from permeating into the light emitting layer 700. Although the encapsulation layer 850 may be made of an inorganic insulating material or formed in a structure in which an inorganic insulating material and an organic insulating material are alternately stacked, the present invention is not necessarily limited thereto.

The color filter layer 900 may be formed on the encapsulation layer 850. The color filter layer 900 may be formed to substantially face the emission areas EA1, EA2, and EA3 in the individual sub-pixels SP1, SP2, and SP3. The color filter layer 900 may include the first color filter CF1, the second color filter CF2, and the third color filter CF3.

Each of the first color filter CF1, the second color filter CF2, and the third color filter CF3 may be any one selected from the group consisting of a red color filter, a green color filter, and a blue color filter. For example, although the first color filter CF1 provided in the first sub-pixel SP1 may include a red color filter, the second color filter CF2 provided in the second sub-pixel SP2 may include a green color filter, and the third color filter CF3 provided in the third sub-pixel SP3 may include a blue color filter, the present invention is not necessarily limited to the above order or colors. The first color filter CF1, the second color filter CF2, and the third color filter CF3 may be selected from the group consisting of the red, green, and blue color filters not to overlap each other.

The black matrix BM may serve to prevent light leakage of the color filter layer 900. Alternatively, the black matrix BM may serve to increase an absorption rate of external light incident from the outside of the display device. Since only a very small amount of incident external light may be reflected by the black matrix BM, it is possible to increase visibility and clarity due to less influence of external light. The black matrix BM is used to decrease contrast caused by bottom reflection of external light and may absorb light having the wavelength in a visible light range. The bottom reflection may indicate that external light is reflected by the lower electrodes 311, 321, and 331.

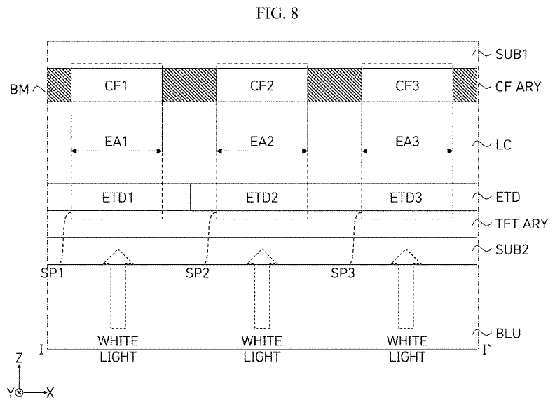

FIG. 8 is a cross-sectional view showing the cross-sectional structure of the pixel according to another embodiment of the present specification.

Referring to FIG. 8, the display device may include two substrates SUB1 and SUB2 opposite to each other and a liquid crystal layer LC formed therebetween. The first substrate SUB1 on which a color filter array CF ARY is formed and the second substrate SUB2 on which a TFT array TFT ARY is formed may be disposed opposite to each other, and the liquid crystal layer LC having dielectric anisotropy may be formed between the first substrate SUB1 and the second substrate SUB2.

The first substrate SUB1 may include the color filter array CF ARY including the first color filter CF1, the second color filter CF2, and the third color filter CF3, and the black matrix BM for preventing light interference between the adjacent color filters. The second substrate SUB2 may include the TFT array TFT ARY including pixel driving signal lines (including data lines to which data voltages are applied and gate lines to which scan pulses are applied) and TFTs formed in each intersection area of the signal lines, and liquid crystal driving electrodes ETD for applying an electric field to the liquid crystal layer LC. The liquid crystal driving electrodes ETD may include a first liquid crystal driving electrode ETD1 opposite to the first color filter CF1, a second liquid crystal driving electrode ETD2 opposite to the second color filter CF2, and a third liquid crystal driving electrode ETD3 opposite to the third color filter CF3. A backlight unit BLU disposed on a back surface of the second substrate SUB2 may include a plurality of light sources for generating light WHITE LIGHT and radiate white light to the second substrate SUB2.

The white light radiated from the backlight unit BLU to the second substrate SUB2 may pass through the liquid crystal driving electrodes ETD and may be applied to the liquid crystal layer LC. In addition, the white light may have birefringence in the liquid crystal layer LC, changed to a desired grayscale, and then incident on the color filter array CF ARY.

The backlight unit BLU may include a plurality of light sources to radiate light WHITE LIGHT to the back surface of the second substrate SUB2. The backlight unit BLU may be implemented as any one of a direct type or an edge type. The direct type backlight unit BLU may have a structure in which a plurality of optical sheets and a diffusion plate are stacked on the back surface of the second substrate SUB2 and a plurality of light sources are disposed under the diffusion plate. The edge type backlight unit BLU may have a structure in which the plurality of optical sheets and a light guide plate are stacked on the back surface of the second substrate SUB2 and the plurality of light sources are disposed on one side surface of the light guide plate. The light sources may be implemented as point light sources such as light emitting diodes (LEDs), but are not limited thereto. The display device may be applied to both a vertical electric field driving method and a horizontal electric field driving method.

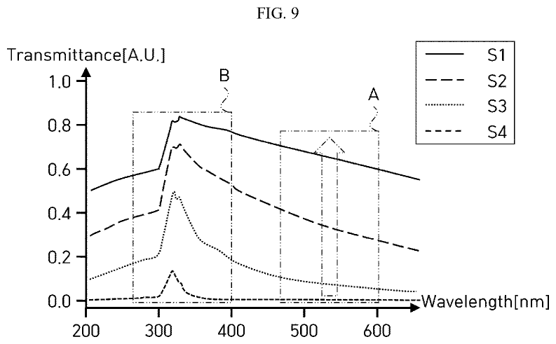

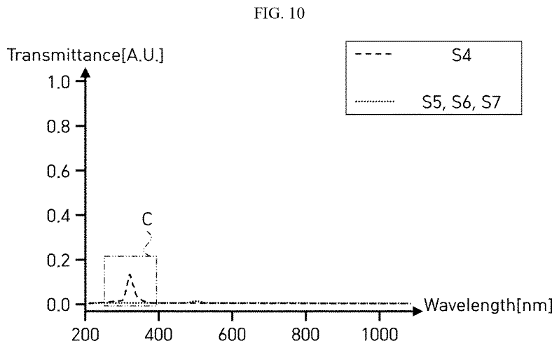

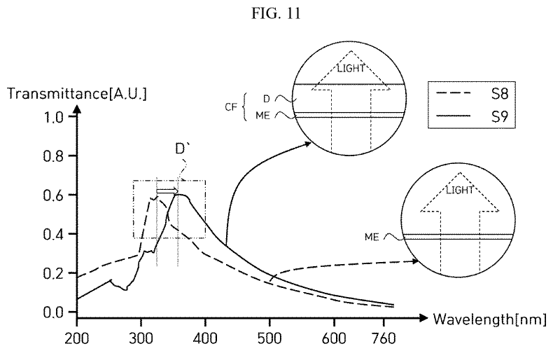

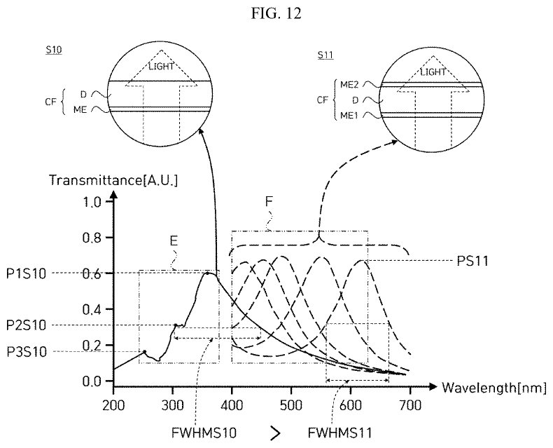

FIG. 9 is a simulation graph showing transmittance distribution by wavelength band according to the thickness of a metal when light is radiated onto the metal. FIG. 10 is a simulation graph showing transmittance distribution by wavelength bands for different metals having the same thickness. FIG. 11 is a simulation graph showing a change in peak wavelength depending on the presence or absence of a dielectric layer. FIG. 12 is a simulation graph showing a change in transmittance distribution of light passing through a single layer or a plurality of metal layers.

In FIGS. 9 to 12, a horizontal axis indicates a wavelength (nm). A vertical axis indicates an arbitrary unit (A.U.) of transmittance. The term “peak wavelength” indicates a wavelength having the transmittance of a peak value (or an extreme Value).

Referring to FIG. 9, Sample 1 S1 shows the transmittance distribution by wavelength band when light is radiated to an Ag metal having the thickness of 100 Å. Sample 2 S2 shows the transmittance distribution by wavelength band when light is radiated to an Ag metal having the thickness of 200 Å. Sample 3 S3 shows the transmittance distribution by wavelength band when light is radiated to an Ag metal having the thickness of 400 Å. Sample 4 S4 shows the transmittance distribution by wavelength band when light is radiated to an Ag metal having the thickness of 1000 Å.

In general, metals have transflective properties in the thickness range of about 100 Å to about 300 Å. However, when the thickness becomes about 1000 Å, the transmittance substantially converges to zero.

A indicates the transmittance according to the thickness of an Ag metal in the visible light region (region having the wavelength of about 380 nm to about 760 nm) that is visible by the human eyes. Referring to A, it is confirmed that the transmittance of the radiated light increases as the thicknesses of the samples S1, S2, S3, and S4 decrease.

B indicates an increase in transmittance according to the wavelength of an Ag metal in an ultraviolet area (area having the wavelength of about 100 nm to about 380 nm) that is invisible by the human eyes. Referring to B, it is confirmed that the transmittance, which tends to increase to some extent as the wavelength of the radiated light decreases, in the range of the wavelength of about 310 nm to about 350 nm has a maximum value.

Referring to Sample 4 S4, it is confirmed that an Ag metal transmits the predetermined amount of light even when having the thickness of 1000 Å.

Referring to FIG. 10, Sample 4 S4 shows the transmittance distribution by wavelength band when light is radiated to the Ag metal having the thickness of 1000 Å. Sample 5 S5 shows the transmittance distribution by wavelength band when light is radiated to an Al metal having the thickness of 1000 Å. Sample 6 S6 shows the transmittance distribution by wavelength band when light is radiated to a Cu metal having the thickness of 1000 Å. Sample 7 S7 shows the transmittance distribution by wavelength band when light is radiated to an Au metal having the thickness of 1000 Å. The transmittance distribution for Sample 5 S5, Sample 6 S6, and Sample 7 S7 was difficult to be identified in the drawing and thus was expressed by a single graph.

C indicates a change in transmittance according to the wavelengths of Ag, Al, Cu, and Au metals having the thickness of 1000 Å in an ultraviolet area (area the wavelength of about 100 nm to about 380 nm) that is invisible by the human eyes. Referring to C, it is confirmed that in the case of other metals other than the Ag metal having the thickness of 1000 Å, the transmittance substantially converges to zero and the Ag metal transmits a predetermined amount of light.

Referring to FIG. 11, Sample 8 S8 shows the transmittance distribution by wavelength band when light LIGHT is radiated to an Ag metal ME having the thickness of 300 Å. Sample 9 S9 shows the transmittance distribution by wavelength band when the light LIGHT is radiated to a color filter CF sample according to the embodiment in which the Ag metal ME having the thickness of 300 Å and a dielectric material D having the thickness of 200 Å are stacked. Specifically, a dielectric material stacked in sample 9 S9 is an organic material. More specifically, the dielectric material stacked in Sample 9 S9 is SiNₓ or SiON deposited as ITO or IZO.

D′ indicates that peak wavelengths are shifted depending on the presence or absence of a dielectric material D in the ultraviolet area (area having the wavelength of about 100 nm to about 380 nm) that is invisible by the human eyes and the visible light area (area having the wavelength of about 380 nm to about 760 nm) that is visible by the human eyes. Referring to D′, it is confirmed that when the dielectric material D is stacked, light LIGHT having the shifted peak wavelength is transmitted into the visible light area that is visible by the human eyes.

It is confirmed that the radiated light LIGHT may be transmitted when a metal ME is used. In addition, it is confirmed that when the dielectric material is stacked on the Ag metal, the transmitted light LIGHT having the wavelength in the visible light area that is visible by the human eyes.

Referring to FIG. 12, Sample 10 S10 shows the transmittance distribution by wavelength band when the light LIGHT is radiated to a color filter CF sample according to the embodiment of Ag having the thickness of 300 Å. Specifically, a dielectric material stacked in Sample 10 S10 is an organic material. More specifically, the dielectric material stacked in Sample 10 S10 is SiNₓ or SiON deposited as ITO or IZO. Sample 11 S11 shows the transmittance distribution by wavelength band when the light LIGHT is radiated to a color filter CF sample according to the embodiments in which the dielectric material D and an Ag metal ME2 having the thickness of 200 Å are stacked on the Ag metal ME1 having the thickness of 200 Å. Specifically, a dielectric material stacked in the embodiments included in Sample 11 S11 is an organic material. More specifically, the dielectric material stacked in the embodiments included in Sample 11 S11 is SiNₓ or SiON deposited as ITO or IZO.

E and F indicate changes in saturation (or purity) of color (e.g., red, green, or blue) depending on whether the light LIGHT additionally passes through the metal layers ME and ME2.

Referring to E, in Sample 10 S10, the transmittance distribution graph by wavelength band may have a plurality of peak values (or extreme values). In Sample 10 S10, the transmittance distribution graph by wavelength band may have a first peak value P1S10, a second peak value P2S10, and a third peak value P3S10. Referring to F, any one of embodiments included in Sample 11 S11 may have a single peak value PS11.

The transmittance distribution graph by wavelength band in Sample 10 S10 may have a full width at half maximum (FWHM) FWHMS10 of Sample 10 S10. The transmittance distribution graph by wavelength band in Sample 11 S11 may have a FWHMS11 of Sample 11 S11. The FWHMS11 of Sample 11 S11 may be smaller than the FWHMS10 of Sample 10 S10.

When the radiated light LIGHT passes through the dielectric material D and then additionally passes through the metal layer ME, it is confirmed that the number of peak values decreases in the transmittance distribution graph. It is confirmed that when the radiated light LIGHT passes through the dielectric material D and then additionally passes through the metal layer ME, there may be no peak value that may appear in the wavelength band of a color (e.g., green or blue) different from the color (e.g., red) to be implemented by an operator. Therefore, it is confirmed that when the light LIGHT additionally passes through the metal layer ME, the saturation of color to be implemented by the operator increases and becomes clearer and darker. It is confirmed that when the radiated light LIGHT passes through the dielectric material D and then additionally passes through the metal layer ME, the FWHM decreases.

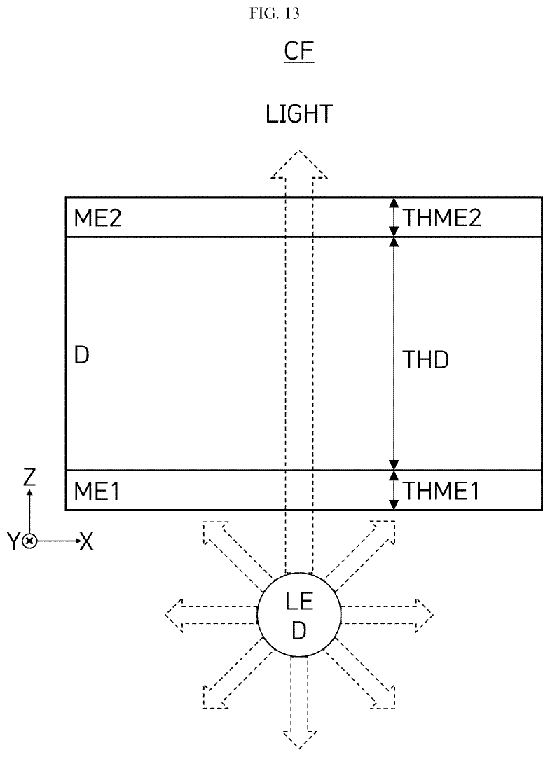

FIG. 13 is a cross-sectional view showing a color filter according to a first embodiment of the present specification.

Referring to FIG. 13, the color filter CF may include the metal layer ME and the dielectric layer D.

The metal layer ME is a layer in which the light LIGHT emitted from the light emitting element LED first reaches and may cause the cavity effect while passing through the light LIGHT to specify the wavelength range of the passing light LIGHT. The metal layer ME may include a first external metal layer ME1 and a second external metal layer ME2. The metal layer ME may additionally include the external metal layer ME with the dielectric layer D interposed therebetween, thereby increasing the cavity effect with reinforcement and/or cancellation. For example, the dielectric layer D is interposed between the first external metal layer ME1 and the second external metal layer ME2, thereby increasing the cavity effect with reinforcement and/or cancellation. As the cavity effect increases, the wavelength distribution of the passing light LIGHT becomes narrower and the FWHM becomes smaller, thereby increasing the color gamut.

The dielectric layer D may be a layer through which the light LIGHT passing through the metal layer ME reaches. The dielectric layer D may shift the peak wavelength of the light LIGHT from the wavelength range of the area (e.g., the ultraviolet area) that is invisible by the human eyes to the wavelength range of the area (e.g., the visible light area) that is visible by the human eyes by allowing the light LIGHT to pass therethrough. The dielectric layer D may adjust the transmittance distribution by wavelength band and peak wavelength of the transmitted light LIGHT, thereby implementing colors (e.g., red, green, and blue) having the wavelength band of a specific range in the area (visible light area) that is visible by the human eyes. For example, blue light may have the wavelength band of 450 nm to 495 nm, green light may have the wavelength band of 495 nm to 570 nm, and red light may have the wavelength band of 620 nm to 760 nm.

One surface of the dielectric layer D may be disposed in contact with the metal layer ME. The dielectric layer D may be disposed such that the one surface thereof is in contact with the first external metal layer ME1 and the other surface is in contact with the second external metal layer ME2. The dielectric layer D may be disposed between the first external metal layer ME1 and the second external metal layer ME2.

The light LIGHT emitted from the light emitting element LED may have a changed wavelength as the light LIGHT passes through the color filter. As described above, the light emitting element LED may be an LED. The light emitting element LED may be an OLED. The light emitting element LED may be a light emitting element LED for backlight and may be a backlight unit.

The light LIGHT emitted from the light emitting element LED may sequentially pass through the metal layer ME and the dielectric layer D. The light LIGHT emitted from the light emitting element LED may sequentially pass through the first external metal layer ME1, the dielectric layer D, and the second external metal layer ME2.

The metal layer ME may be disposed on the light emitting element LED, and the dielectric layer D may be disposed on the metal layer ME. The first external metal layer ME1 may be disposed on the light emitting element LED, the dielectric layer D may be disposed on the second external metal layer ME2, and the first external metal layer ME1 may be disposed on the dielectric layer D.

The color filter according to the embodiment may have a double-layer structure in which the metal layer ME and the dielectric layer D are stacked. The color filter may have a triple-layer structure in which the first external metal layer ME1, the dielectric layer D, and the second external metal layer ME2 are stacked. The light emitting element LED may emit light LIGHT radially in addition to a direction in which the color filter is disposed. The light LIGHT emitted from a light emitting element LED may have a substantially fully diffused surface (Lambertian surface). At least a portion of the light LIGHT may reach the metal layer ME earlier than the dielectric layer D. At least a portion of the light LIGHT may first reach the first external metal layer ME1, then reach the dielectric layer D, and then reach the second external metal layer ME2.

The metal layer ME may be formed of at least one selected from the group consisting of Ag, Au, Al, Cu, and alloys thereof. Preferably, the metal layer ME may be formed of Ag or an alloy layer including at least Ag. For example, the metal layer ME may be formed of Ag: Mg, APC (an alloy of Ag, Pd, and Cu), Ag: Yb, or Ag: Cu.

A thickness THME of the metal layer ME may be set in the range through which the light LIGHT may be transmitted.

A thickness THME1 of the first external metal layer ME1 may be in the range of 100 Å to 1000 Å. When the thickness THME1 of the first external metal layer ME1 is smaller than 100 Å, it is possible to excessively increase the transmittance of the light LIGHT, thereby decreasing the cavity effect, and when the thickness THME1 is greater than 1000 Å, the transmittance may be decreased, and thus the light LIGHT may not pass through the metal layer ME. Preferably, the thickness THME1 of the first external metal layer ME1 may be in the range of 100 Å to 400 Å. When the thickness THME1 of the first external metal layer ME1 is greater than 400 Å, the transmittance may decrease, thereby decreasing the wavelength range of the transmitted light LIGHT and decreasing the color gamut of the color filter using the same.

A thickness THME2 of the second external metal layer ME2 may be 50% to 150% of the thickness THME1 of the first external metal layer ME1. Preferably, the thickness THME2 of the second external metal layer ME2 may be 80% to 120% of the thickness THME1 of the first external metal layer ME1. More preferably, the thickness THME2 of the second external metal layer ME2 may be substantially the same as the thickness THME1 of the first external metal layer ME1.

The thickness THME2 of the second external metal layer ME2 may be in the range of 100 Å to 1000 Å. When the thickness THME2 of the second external metal layer ME2 is smaller than 100 Å, it is possible to excessively increase the transmittance of the light LIGHT, thereby decreasing the cavity effect, and when the thickness THME2 is greater than 1000 Å, the transmittance may be decreased, and thus the light LIGHT may not pass through the metal layer ME. Preferably, the thickness THME2 of the second external metal layer ME2 may be in the range of 100 Å to 400 Å. When the thickness THME2 of the second external metal layer ME2 is greater than 400 Å, the transmittance may decrease, thereby decreasing the wavelength range of the transmitted light LIGHT and decreasing the color gamut of the color filter using the same.

The dielectric layer D may include a dielectric material, which is an insulating material having polarity in an electric field. The dielectric material may be an organic material, an inorganic material, or oxide. Preferably, the dielectric material may be an organic material or oxide. For example, the dielectric layer D may be formed of SiNₓ, SiO₂, or SiON.

Films may be formed on the dielectric material by sputtering as well as chemical deposition such as chemical vapor deposition (CVD). For example, the dielectric material may be formed by a transparent conductive oxide (TCO)-series material such as ITO, IZO, or ZnO

The metal layer ME may be formed of at least one selected from the group consisting of Ag, Au, Al, Cu, and alloys thereof. Preferably, the metal layer ME may be formed of Ag or an alloy layer including at least Ag. For example, the metal layer ME may be formed of Ag: Mg, APC (an alloy of Ag, Pd, and Cu), Ag: Yb, or Ag: Cu.

A thickness THD of the dielectric layer may be 275% to 2100% of the thickness THME 1 of the first external metal layer ME1. By adjusting the thickness THD of the dielectric layer, the color implemented by the light LIGHT passing through the color filter may be changed. The thickness THD of the dielectric layer may be in the range of 1100 Å to 2100 Å.

The thickness THD of the dielectric layer may be 275% to 1200% of the thickness THME1 of the first external metal layer ME1. By adjusting the thickness THD of the dielectric layer to the above range, the red color may be implemented by the light LIGHT passing through the color filter. The thickness THME1 of the first external metal layer ME1 may be in the range of 100 Å to 400 Å, and the thickness THD of the dielectric layer may be in the range of 1100 Å to 1200 Å.

The thickness THD of the dielectric layer may be 375% to 1800% of the thickness THME1 of the first external metal layer ME1. By adjusting the thickness THD of the dielectric layer to the above range, the blue color may be implemented by the light LIGHT passing through the color filter. The thickness THME1 of the first external metal layer ME1 may be in the range of 100 Å to 400 Å, and the thickness THD of the dielectric layer may be in the range of 1500 Å to 1800 Å.

The thickness THD of the dielectric layer may be 512.5% to 2100% of the thickness THME 1 of the first external metal layer ME1. By adjusting the thickness THD of the dielectric layer to the above range, the green color may be implemented by the light LIGHT passing through the color filter. The thickness THME1 of the first external metal layer ME1 may be in the range of 100 Å to 400 Å, and the thickness THD of the dielectric layer may be in the range of 2050 Å to 2100 Å.

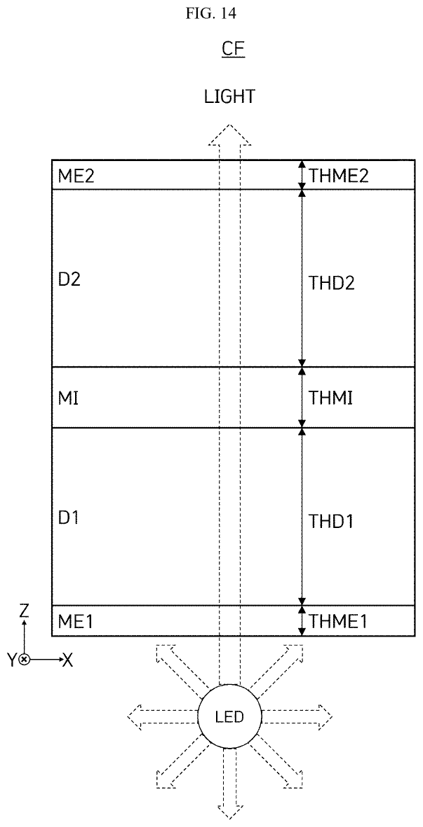

FIG. 14 is a cross-sectional view showing a color filter according to a second embodiment of the present specification. Components that perform substantially the same function as components according to the above-described embodiments are denoted by the same reference numerals, and detailed descriptions thereof are omitted.

Referring to FIG. 14, the metal layer may include the first external metal layer ME1, the second external metal layer ME2, and an internal metal layer MI. The metal layer may additionally include the internal metal layer MI with the dielectric layer interposed therebetween, thereby increasing the cavity effect with reinforcement and/or cancellation. For example, the internal metal layer MI is between the first external metal layer ME1 and the second external metal layer ME2, and the dielectric layers are disposed between the internal metal layer MI and the first external metal layer ME1, as well as the internal metal layer MI and the second external metal layer ME2, respectively, thereby increasing the cavity effect with reinforcement and/or cancellation. As the cavity effect increases, the wavelength distribution of the passing light LIGHT becomes narrower and the FWHM becomes smaller, thereby increasing the color gamut.

The dielectric layer may include the first dielectric layer D1 and the second dielectric layer D2. The dielectric layer may include the plurality of dielectric layers D1 and D2 with the internal metal layer MI interposed therebetween, thereby increasing the cavity effect. For example, the internal metal layer MI is between the first external metal layer ME1 and the second external metal layer ME2, and the first dielectric layer D1 and the second dielectric layer D2 are disposed between the internal metal layer MI and the first external metal layer ME1, as well as the internal metal layer MI and the second external metal layer ME2, respectively, thereby increasing the cavity effect with reinforcement and/or cancellation, but the present disclosure is not limited thereto.

The dielectric layer may be disposed such that the one surface thereof is in contact with the first external metal layer ME1 and the other surface is in contact with the second external metal layer ME2. The dielectric layer may be disposed between the first external metal layer ME1 and the second external metal layer ME2.

The first dielectric layer D1 may be disposed such that one surface thereof is in contact with the first external metal layer ME1 and the other surface is in contact with the internal metal layer MI. The internal metal layer M1 may be disposed such that one surface thereof is in contact with the first dielectric layer D1 and the other surface is in contact with the second dielectric layer D2. The second dielectric layer D2 may be disposed such that one surface thereof is in contact with the internal metal layer MI and the other surface is in contact with the second external metal layer ME2.

The light LIGHT emitted from the light emitting element LED may sequentially pass through the first external metal layer ME1, the first dielectric layer D1, the internal metal layer MI, the second dielectric layer D2, and the second external metal layer ME2.

The first external metal layer ME1 may be disposed on the light emitting element LED, the first dielectric layer D1 may be disposed on the first external metal layer ME1, the internal metal layer M1 may be disposed on the first dielectric layer D1, the second dielectric layer D2 may be disposed on the internal metal layer MI, and the second external metal layer ME2 may be disposed on the second dielectric layer D2.

The color filter according to the embodiment may have a quintuple-layer including the first external metal layer ME1, the first dielectric layer D1, the internal metal layer MI, the second dielectric layer D2, and the second external metal layer ME2. At least a portion of the light LIGHT emitted from the light emitting element LED may first reach the first external metal layer ME1, and the sequentially reach the first dielectric layer D1, reach the internal metal layer MI, and reach the second dielectric layer D2, and the second external metal layer ME2.

The thickness THMI of the internal metal layer M1 may be 50% to 150% of the sum of the thickness THME1 of the first external metal layer ME1 and the thickness THME2 of the second external metal layer ME2. Preferably, the thickness THMI of the internal metal layer MI may be 80% to 120% of the sum of the thickness THME1 of the first external metal layer ME1 and the thickness THME2 of the second external metal layer ME2. More preferably, the thickness THMI of the internal metal layer M1 may be substantially the same as the sum of the thickness THME1 of the first external metal layer ME1 and the thickness THME2 of the second external metal layer ME2.

The thickness THMI of the internal metal layer M1 may be in the range of 200 Å to 2000 Å. When the thickness THMI of the internal metal layer MI is smaller than 200 Å, it is possible to excessively increase the transmittance of the light LIGHT, thereby reducing the cavity effect, and when the thickness THMI is greater than 2000 Å, it is possible to reduce the transmittance, and thus the light LIGHT may not pass through the metal layer. Preferably, the thickness THMI of the internal metal layer M1 may be in the range of 200 Å to 800 Å. When the thickness THMI of the internal metal layer MI is greater than 800 Å, the transmittance may decrease, thereby decreasing the wavelength range of the transmitted light LIGHT and reducing the color gamut of the color filter using the same.

The thickness THD2 of the second dielectric layer D2 may be 50% to 150% of the thickness THD1 of the first dielectric layer D1. Preferably, the thickness THD2 of the second dielectric layer D2 may be 80% to 120% of the thickness THD1 of the first dielectric layer D1. More preferably, the thickness THD2 of the second dielectric layer D2 may be substantially the same as the thickness THD1 of the first dielectric layer D1.

The thickness THD1 of the first dielectric layer D1 may be 275% to 2100% of the thickness THME1 of the first external metal layer ME1. By adjusting the thickness THD1 of the first dielectric layer D1, the color implemented by the light LIGHT passing through the color filter may be changed. The thickness THD1 of the first dielectric layer D1 may be in the range of 1100 Å to 2100 Å.

The thickness THD1 of the first dielectric layer D1 may be 275% to 1200% of the thickness THME1 of the first external metal layer ME1. By adjusting the thickness THD1 of the first dielectric layer D1 to the above range, the red color may be implemented by the light LIGHT passing through the color filter. The thickness THME1 of the first external metal layer ME1 may be in the range of 100 Å to 400 Å, and the thickness THD1 of the first dielectric layer D1 may be in the range of 1100 Å to 1200 Å.

The thickness THD1 of the first dielectric layer D1 may be 375% to 1800% of the thickness THME1 of the first external metal layer ME1. By adjusting the thickness THD1 of the first dielectric layer D1 to the above range, the blue color may be implemented by the light LIGHT passing through the color filter. The thickness THME1 of the first external metal layer ME1 may be in the range of 100 Å to 400 Å, and the thickness THD1 of the first dielectric layer D1 may be in the range of 1500 Å to 1800 Å.

The thickness THD1 of the first dielectric layer D1 may be 512.5% to 2100% of the thickness THME1 of the first external metal layer ME1. By adjusting the thickness THD1 of the first dielectric layer D1 to the above range, the green color may be implemented by the light LIGHT passing through the color filter. The thickness THME1 of the first external metal layer ME1 may be in the range of 100 Å to 400 Å, and the thickness THD1 of the first dielectric layer D1 may be in the range of 2050 Å to 2100 Å.

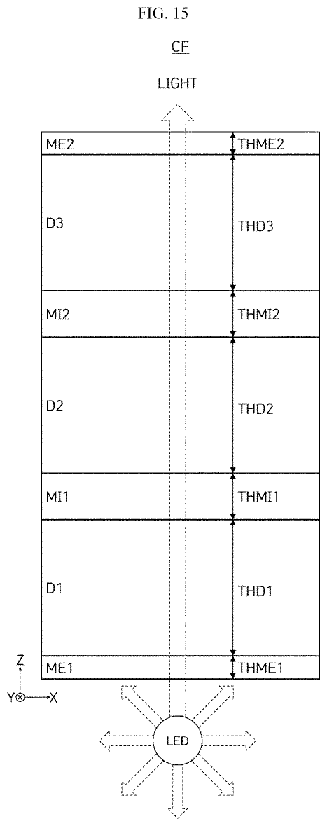

FIG. 15 is a cross-sectional view showing a color filter according to a third embodiment of the present specification. Components that perform substantially the same function as components according to the above-described embodiments are denoted by the same reference numerals, and detailed descriptions thereof are omitted.

Referring to FIG. 15, the metal layer may include the first external metal layer ME1, the second external metal layer ME2, a first internal metal layer MI1, and a second internal metal layer MI2.

The dielectric layer may include the first dielectric layer D1, the second dielectric layer D2, and a third dielectric layer D3.

The dielectric layer may be disposed such that the one surface thereof is in contact with the first external metal layer ME1 and the other surface is in contact with the second external metal layer ME2. The dielectric layer may be disposed between the first external metal layer ME1 and the second external metal layer ME2.

The first dielectric layer D1 may be disposed such that one surface thereof is in contact with the first external metal layer ME1 and the other surface is in contact with the internal metal layer MI1. The first internal metal layer MI1 may be disposed such that one surface thereof is in contact with the first dielectric layer D1 and the other surface is in contact with the second dielectric layer D2. The second dielectric layer D2 may be disposed such that one surface thereof is in contact with the first internal metal layer MI1 and the other surface is in contact with the second internal metal layer MI2. The second internal metal layer MI2 may be disposed such that one surface thereof is in contact with the second dielectric layer D2 and the other surface is in contact with the third dielectric layer D3. The third dielectric layer D3 may be disposed such that one surface thereof is in contact with the second internal metal layer MI2 and the other surface is in contact with the second external metal layer ME2.

The light LIGHT emitted from the light emitting element LED may sequentially pass through the first external metal layer ME1, the first dielectric layer D1, the first internal metal layer MI1, the second dielectric layer D2, the second internal metal layer MI2, the third dielectric layer D3, and the second external metal layer ME2.

The first external metal layer ME may be disposed on the light emitting element LED, the first dielectric layer D1 may be disposed on the first external metal layer ME1, the first internal metal layer MI1 may be disposed on the first dielectric layer D1, the second dielectric layer D2 may be disposed on the first internal metal layer MI1, the second internal metal layer MI2 may be disposed on the second dielectric layer D2, the third dielectric layer D3 may be disposed on the second internal metal layer MI2, and the second external metal layer ME2 may be disposed on the third dielectric layer D3.

The color filter according to the embodiment may have a seven-layer structure in which the first external metal layer ME1, the first dielectric layer D1, the first internal metal layer MI1, the second dielectric layer D2, the second internal metal layer MI2, the third dielectric layer D3, and the second external metal layer ME2 may be stacked. At least a portion of the light LIGHT emitted from the light emitting element LED may first reach the first external metal layer ME1, and then sequentially reach the first dielectric layer D1, the first internal metal layer MI1, the second dielectric layer D2, the second internal metal layer MI2, the third dielectric layer D3, and the second external metal layer ME2.

The thickness THMI1 of the first internal metal layer MI1 and the thickness THMI2 of the second internal metal layer MI2 may each be 50% to 150% of the sum of the thickness THME1 of the first external metal layer of the first external metal layer ME1 and the thickness THME2 of the second external metal layer ME2. Preferably, the thickness THMI1 of the first internal metal layer MI1 and the thickness THMI2 of the second internal metal layer MI2 may be 80% to 120% of the sum of the thickness THME1 of the first external metal layer ME1 and the thickness THMI2 of the second external metal layer ME2. More preferably, the thickness THMI1 of the first internal metal layer MI1 and the thickness THMI2 of the second internal metal layer MI2 may each be substantially the same as the sum of the thickness THME1 of the first external metal layer ME1 and the thickness THME2 of the second external metal layer ME2.

The thickness THMI1 of the first internal metal layer MI1 and the thickness THMI2 of the second internal metal layer MI2 may each be in the range of 200 Å to 2000 Å. When the thickness THMI1 of the first internal metal layer MI1 or the thickness THMI2 of the second internal metal layer MI2 is smaller than 200 Å, the transmittance of the light LIGHT may excessively increase, thereby reducing the cavity effect, and when the thickness THMI1 is greater than 2000 Å, the transmittance may decrease, and thus the light LIGHT may not pass through the metal layer. Preferably, the thickness THMI1 of the first internal metal layer MI1 and the thickness THMI2 of the second internal metal layer MI2 may each be in the range of 200 Å to 800 Å. When the thickness THMI1 of the first internal metal layer MI1 or the thickness THMI2 of the second internal metal layer MI2 is greater than 800 Å, the transmittance may decrease, thereby decreasing the wavelength range of the light LIGHT and decreasing the color gamut of the color filter using the same.

The thickness THD2 of the second dielectric layer D2 may be 50% to 150% of the thickness THD1 of the first dielectric layer D1. Preferably, the thickness THD2 of the second dielectric layer D2 may be 80% to 120% of the thickness THD1 of the first dielectric layer D1. More preferably, the thickness THD2 of the second dielectric layer D2 may be substantially the same as the thickness THD1 of the first dielectric layer D1.

The thickness THD3 of the third dielectric layer D3 may be 50% to 150% of the thickness THD1 of the first dielectric layer D1. Preferably, the thickness THD3 of the third dielectric layer D3 may be 80% to 120% of the thickness THD1 of the first dielectric layer D1. More preferably, the thickness THD3 of the third dielectric layer D3 may be substantially the same as the thickness THD1 of the first dielectric layer D1.

The thickness THD1 of the first dielectric layer D1 may be 275% to 2100% of the thickness THME1 of the first external metal layer ME1. By adjusting the thickness THD1 of the first dielectric layer D1, the color implemented by the light LIGHT passing through the color filter may be changed. The thickness THD1 of the first dielectric layer D1 may be in the range of 1100 Å to 2100 Å.

The thickness THD1 of the first dielectric layer D1 may be 275% to 1200% of the thickness THME1 of the first external metal layer ME1. By adjusting the thickness THD1 of the first dielectric layer D1 to the above range, the red color may be implemented by the light LIGHT passing through the color filter. The thickness THME1 of the first external metal layer ME1 may be in the range of 100 Å to 400 Å, and the thickness THD1 of the first dielectric layer D1 may be in the range of 1100 Å to 1200 Å.

The thickness THD1 of the first dielectric layer D1 may be 375% to 1800% of the thickness THME1 of the first external metal layer ME1. By adjusting the thickness THD1 of the first dielectric layer D1 to the above range, the blue color may be implemented by the light LIGHT passing through the color filter. The thickness THME1 of the first external metal layer ME1 may be in the range of 100 Å to 400 Å, and the thickness THD1 of the first dielectric layer D1 may be in the range of 1500 Å to 1800 Å.

The thickness THD1 of the first dielectric layer D1 may be 512.5% to 2100% of the thickness THME1 of the first external metal layer ME1. By adjusting the thickness THD1 of the first dielectric layer D1 to the above range, the green color may be implemented by the light LIGHT passing through the color filter. The thickness THME1 of the first external metal layer ME1 may be in the range of 100 Å to 400 Å, and the thickness THD1 of the first dielectric layer D1 may be in the range of 2050 Å to 2100 Å.

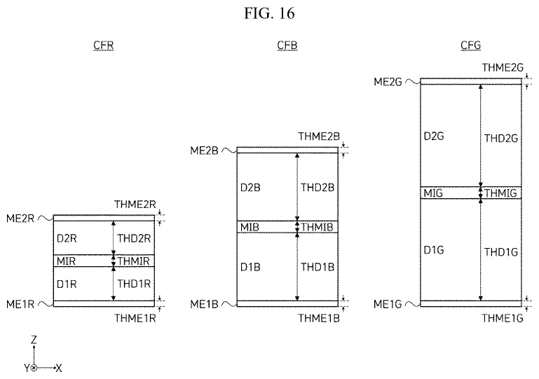

FIG. 16 is a cross-sectional view showing the relationship between color filters that implement colors of red, green, and blue in the present specification. Components that perform substantially the same function as components according to the above-described embodiments are denoted by the same reference numerals, and detailed descriptions thereof are omitted. For example, the above description of the color filter according to the second embodiment may be applied to first and second external metal layers ME1R and ME2R, a red internal metal layer MIR, and first and second dielectric layers D1R and D2R in the red color filter CFR.

Referring to FIG. 16, the pixel may include a first sub-pixel including a red color filter CFR implementing a red color, a second sub-pixel including a blue color filter CFB implementing a blue color, and a third sub-pixel including a green color filter CFG implementing a green color. The red color filter CFR, the blue color filter CFB, or the green color filter CFG may each correspond to any one of the first to third color filters CF1, CF2, and CF3 according to FIGS. 13 to 15.

Each of the color filters CFR, CFB, and CFG may include the metal layer M and the dielectric layer D. Each of the color filters CFR, CFB, and CFG may have a quintuple-layer structure in which the first external metal layer ME1, the first dielectric layer D1, the internal metal layer MI, the second dielectric layer D2, and the second external metal layer ME2 are stacked. However, the stacking structure or the coupling relationship thereof is not limited thereto and may be appropriately modified with reference to the above-described embodiments according to FIGS. 13 to 15. For example, each of the color filters CFR, CFB, and CFG may have a triple-layer structure in which the first external metal layer ME1, the dielectric layer D, and the second external metal layer ME2 are stacked.

The red color filter CFR may include the first red external metal layer ME1R, the second red external metal layer ME2R, the red internal metal layer MIR, the first red dielectric layer DIR, and the second red dielectric layer D2R. The blue color filter CFB may include a first blue external metal layer ME1B, a second blue external metal layer ME2B, a blue internal metal layer MIB, a first blue dielectric layer D1B, and a second blue dielectric layer D2B. The green color filter CFG may include a first green external metal layer ME1G, a second green external metal layer ME2G, a green internal metal layer MIG, a first green dielectric layer DIG, and a second green dielectric layer D2G.

A thickness THME1B of the first blue external metal layer ME1B may be 50% to 150% of a thickness THME1R of the first red external metal layer ME1R. A thickness THME1G of the first green external metal layer ME1G may be 50% to 150% of the thickness THME1R of the first red external metal layer ME1R. Preferably, the thickness THME1B of the first blue external metal layer ME1B may be 80% to 120% of the thickness THME1R of the first red external metal layer ME1R. Preferably, the thickness THME1G of the first green external metal layer ME1G may be 80% to 120% of the thickness THME1R of the first red external metal layer ME1R. More preferably, the thickness THME1B of the first blue external metal layer ME1B may be substantially the same as the thickness THME1R of the first red external metal layer ME1R. More preferably, the thickness THME1G of the first green external metal layer ME1G may be substantially the same as the thickness THME1R of the first red external metal layer ME1R.

The thickness THMIB of the blue internal metal layer MIB may be 50% to 150% of the sum of the thickness THME1R of the first red external metal layer ME1R and the thickness THME2R of the second red external metal layer ME2R. The thickness THMIG of the green internal metal layer MIG may be 50% to 150% of the sum of the thickness THME1R of the first red external metal layer ME1R and the thickness THME2R of the second red external metal layer ME2R. Preferably, the thickness THMIB of the blue internal metal layer MIB may be 80% to 120% of the sum of the thickness THME1R of the first red external metal layer ME1R and the thickness THME2R of the second red external metal layer ME2R. Preferably, the thickness THMIG of the green internal metal layer MIG may be 80% to 120% of the sum of the thickness THME1R of the first red external metal layer ME1R and the thickness THME2R of the second red external metal layer ME2R. More preferably, the thickness THMIB of the blue internal metal layer MIB may be substantially the same as the sum of the thickness THME1R of the first red external metal layer ME1R and the thickness THME2R of the second red external metal layer ME2R. More preferably, the thickness THMIG of the green internal metal layer MIG may be substantially the same as the sum of the thickness THME1R of the first red external metal layer ME1R and the thickness THME2R of the second red external metal layer ME2R.

The thickness THD1B of the first blue dielectric layer DIB may be 125% to 164% of the thickness THD1R of the first red dielectric layer DIR. The thickness THD1R of the first red dielectric layer DIR may be in the range of 1100 Å to 1200 Å, and the thickness THD1B of the first blue dielectric layer DIB may be in the range of 1500 Å to 1800 Å.

The thickness THD1G of the first green dielectric layer DIG may be 171% to 191% of the thickness THD1R of the first red dielectric layer DIR. The thickness THD1R of the first red dielectric layer DIR may be in the range of 1100 Å to 1200 Å, and the thickness THD1G of the first green dielectric layer DIG may be in the range of 2050 Å to 2100 Å.

The thickness THD1G of the first green dielectric layer DIG may be 114% to 140% of the thickness THD1B of the first blue dielectric layer DIB. The thickness THD1B of the first blue dielectric layer DIB may be in the range of 1100 Å to 1200 Å, and the thickness THD1G of the first green dielectric layer DIG may be in the range of 2050 Å to 2100 Å.

The above-described ratio or numerical range of the thickness according to FIGS. 13 to 15 may be appropriately modified in the range described herein. For example, since the thickness THMIB of the blue internal metal layer MIB may be 50% to 150% of the sum of the thickness THME1R of the first red external metal layer ME1R and the thickness THME2R of the second red external metal layer ME2R, the thickness THME2R of the second red external metal layer ME2R may be 50% to 150% of the thickness THME1R of the first red external metal layer ME1R, and the thickness THD1R of the first red dielectric layer DIR may be 275% to 1200% of the thickness THME1R of the first red external metal layer ME1R, from the relationship therebetween, a ratio of the thickness THMIB of the blue internal metal layer MIB and the thickness THD1R of the first red dielectric layer DIR may be derived, and thus even the numerical ranges not described in the present specification may be included in the claims described in the present specification.

Since the thicknesses THD1R and THD2R of the dielectric layers DIR and D2R in the red color filter CFR, the thicknesses THD1B and THD2B of the dielectric layers DIB and D2B in the blue color filter CFB, and the thicknesses THD1G and THD2G of the dielectric layers DIG and D2G in the green color filter CFG are all different, it is possible to implement the micro-cavity effect. The micro-cavity effect can be understood similarly to the above description.

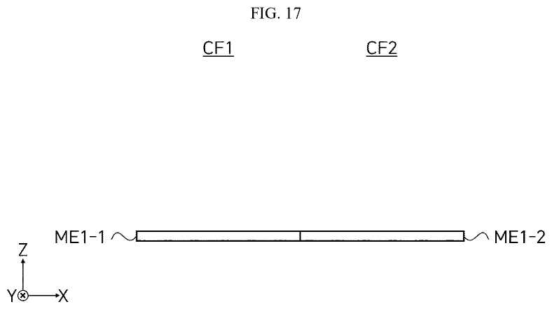

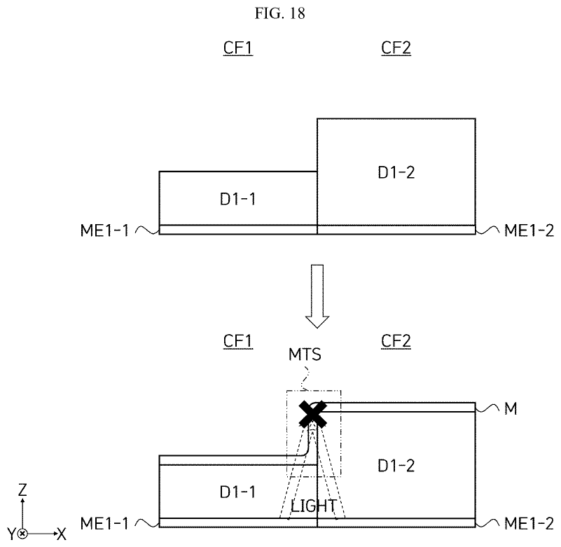

FIGS. 17 to 23 are schematic cross-sectional views for describing a thickness step of a metal layer according to various embodiments of the present specification. FIGS. 18 to 23 show that whether a black matrix is formed or the thicknesses of the formed black matrix are different.

Referring to FIG. 17, first external metal layers ME1-1 and ME1-2 may be stacked in the process of manufacturing the color filters CF1 and CF2 according to the embodiments of the present specification.

Referring to FIGS. 18 to 23, first dielectric layers D1-1 and D1-2 may be stacked on the first external metal layers ME1-1 and ME1-2. As described above, the dielectric layers D1-1 and D1-2 included in the color filter CF according to the present specification may have different thicknesses.

The 1-1 dielectric layer D1-1 included in the first color filter CF1 and the thickness of the 1-2 dielectric layer D1-2 included in the second color filter CF2 may be formed to have different thicknesses. The thicknesses of the dielectric layers D1-1 and D1-2 may be adjusted using a manufacturing process (e.g., a fine metal mask (FMM) process) known to those skilled in the art.

Referring to FIG. 18, a black matrix may not be formed between the first color filter CF1 and the second color filter CF2. Referring to an arrow, the metal layer M may be subsequently stacked on the dielectric layers D1-1 and D1-2. The metal layer M may include the above-described internal metal layer or second external metal layer. The thickness of the metal layer M formed on the color filters CF1 and CF2 in the Z-axis direction may be substantially the same except for a thickness stepped portion MTS below.

Since the color filters CF according to the present specification may have the dielectric layers D1-1 and D1-2 having different thicknesses, the metal layer M stacked on the dielectric layers D1-1 and D1-2 having different thicknesses may include the thickness stepped portion MTS of which the thickness in the Z-axis direction is not substantially the same.

The thickness stepped portion MTS of the metal layer M may be formed by the dielectric layers D1-1 and D1-2 already formed in different thicknesses in the process of stacking the metal layer M. Since the thickness stepped portion MTS may be formed in the metal layer M, referring to the above description of the thickness and transmittance of the metal, light may not pass through the relatively thick portion. Since the thickness stepped portion MTS may perform a light blocking function, it is possible to increase the color gamut of the display device.

The thickness stepped portion MTS may overlap the color filter (e.g., CF1) having a smaller thickness in the Z-axis direction among the first color filter CF1 and the second color filter CF2. The thickness stepped portion MTS may be disposed at a boundary between the dielectric layers D1-1 and D1-2 with different thicknesses. The thickness stepped portion MTS may be removed in the finally formed color filter.

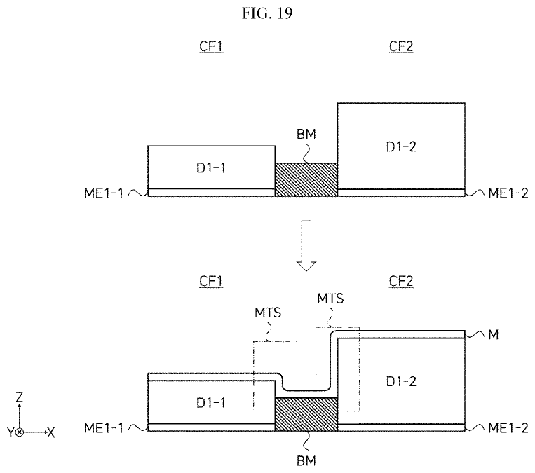

Referring to FIG. 19, the black matrix BM may be formed between the first color filter CF1 and the second color filter CF2. The thickness of the black matrix BM may be smaller than that of the color filter (e.g., CF1) having the smaller thickness among the first color filter CF1 and the second color filter CF2. Referring to an arrow, the metal layer M may be subsequently stacked on the dielectric layers D1-1 and D1-2. The thickness stepped portion MTS may overlap the black matrix BM in the Z-axis direction. The thickness stepped portion MTS may be disposed between the color filters CF1 and CF2 having different thicknesses. The thickness stepped portion MTS may be disposed at a boundary between the dielectric layers D1-1 and D1-2 having different thicknesses and the black matrix BM.

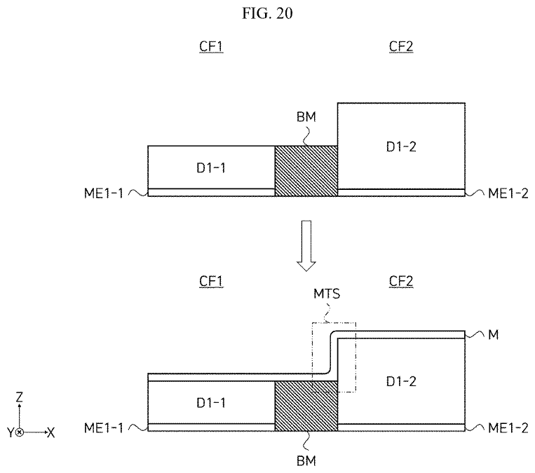

Referring to FIG. 20, the black matrix BM may be formed between the first color filter CF1 and the second color filter CF2. The thickness of the black matrix BM may be substantially the same as that of the color filter (e.g., CF1) having the smaller thickness among the first color filter CF1 and the second color filter CF2. Referring to an arrow, the metal layer M may be subsequently stacked on the dielectric layers D1-1 and D1-2. The thickness stepped portion MTS may overlap the black matrix BM in the Z-axis direction. The thickness stepped portion MTS may be disposed between the color filters CF1 and CF2 having different thicknesses. The thickness stepped portion MTS may be disposed at a boundary between the dielectric layers D1-1 and D1-2 having different thicknesses and the black matrix BM.

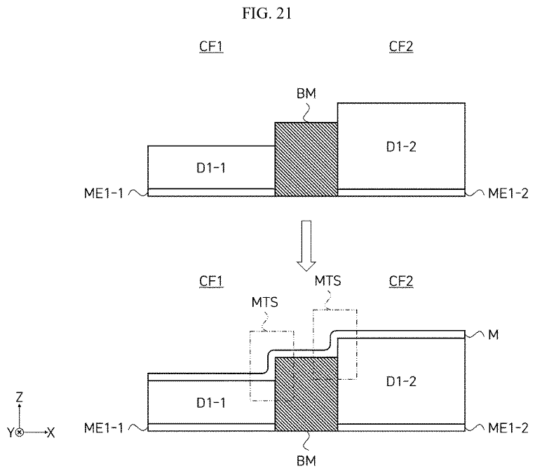

Referring to FIG. 21, the black matrix BM may be formed between the first color filter CF1 and the second color filter CF2. The thickness of the black matrix BM may be greater than that of the color filter (e.g., CF1) having the smaller thickness and smaller than that of the color filter (e.g., CF2) having a greater thickness among the first color filter CF1 and the second color filter CF2. Referring to an arrow, the metal layer M may be subsequently stacked on the dielectric layers D1-1 and D1-2. The thickness stepped portion MTS may overlap the black matrix BM in the Z-axis direction. The thickness stepped portion MTS may overlap the first color filter CF1 in the Z-axis direction. The thickness stepped portion MTS may be disposed between the color filters CF1 and CF2 having different thicknesses and disposed to overlap at least one of the color filters CF1 and CF2 having different thicknesses in the thickness direction. The thickness stepped portion MTS may be disposed at a boundary between the dielectric layers D1-1 and D1-2 having different thicknesses and the black matrix BM.

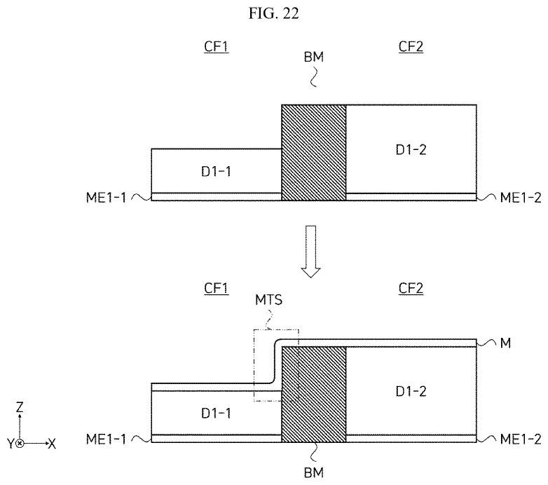

Referring to FIG. 22, the black matrix BM may be formed between the first color filter CF1 and the second color filter CF2. The thickness of the black matrix BM may be substantially the same as that of the color filter having the greater thickness among the first color filter CF1 and the second color filter CF2. Referring to an arrow, the metal layer M may be subsequently stacked on the dielectric layers D1-1 and D1-2. The thickness stepped portion MTS may overlap the first color filter CF1 in the Z-axis direction. The thickness stepped portion MTS may be disposed to overlap at least one of the color filters CF1 and CF2 having different thicknesses in the thickness direction. The thickness stepped portion MTS may be disposed at a boundary between the dielectric layers D1-1 and D1-2 having different thicknesses and the black matrix BM.

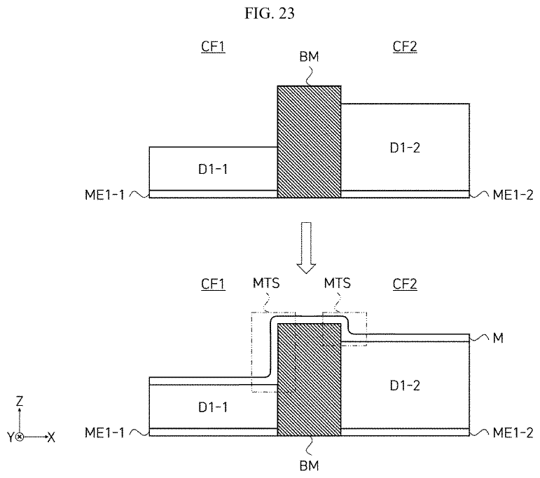

Referring to FIG. 23, the black matrix BM may be formed between the first color filter CF1 and the second color filter CF2. The thickness of the black matrix BM may be greater than that of the color filter having the greater thickness among the first color filter CF1 and the second color filter CF2. Referring to the arrow, the metal layer M may be subsequently stacked on the dielectric layers D1-1 and D1-2. The thickness stepped portion MTS may overlap the first color filter CF1 in the Z-axis direction. The thickness stepped portion MTS may overlap the second color filter CF2 in the Z-axis direction. The thickness stepped portion MTS may be disposed to overlap at least one of the color filters CF1 and CF2 having different thicknesses in the thickness direction. The thickness stepped portion MTS may be disposed at a boundary between the dielectric layers D1-1 and D1-2 having different thicknesses and the black matrix BM.

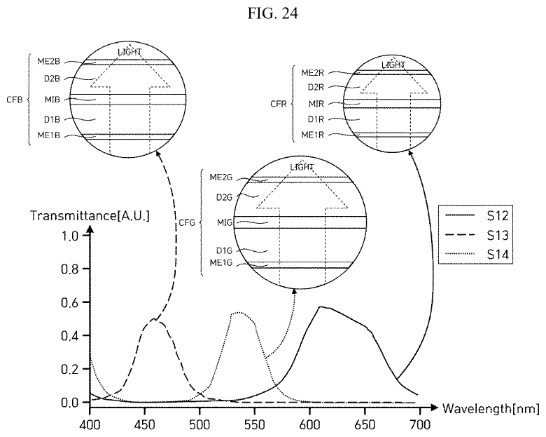

FIG. 24 is a simulation graph showing transmittance distribution by wavelength band according to the thickness of a dielectric layer when light is radiated to the color filter.

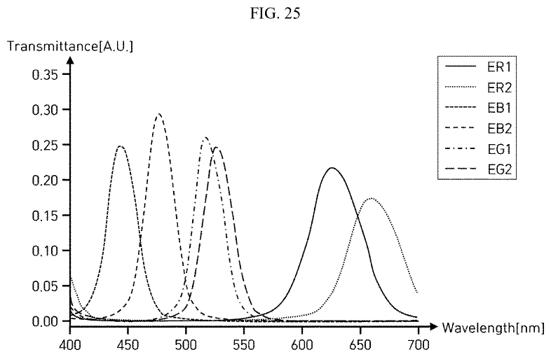

In FIGS. 24 and 25, a horizontal axis indicates a wavelength (nm). A vertical axis indicates an arbitrary unit (A.U.) of transmittance.

Referring to FIG. 24, the pixel may include the first sub-pixel including the red color filter CFR implementing the red color, the second sub-pixel including the blue color filter CFB implementing the blue color, and the third sub-pixel including the green color filter CFG implementing the green color. Blue light may have the wavelength band of 450 nm to 495 nm, green light may have the wavelength band of 495 nm to 570 nm, and red light may have the wavelength band of 620 nm to 760 nm. However, the present specification is not specific thereto, and there may be a difference between upper and lower limits of the wavelength band for the same color depending on an operator.

The light emitted from the first sub-pixel may have the peak wavelength of 600 nm to 650 nm. The light emitted from the second sub-pixel may have the peak wavelength of 450 nm to 495 nm. The light emitted from the third sub-pixel may have the peak wavelength of 495 nm to 570 nm.

However, this is illustrative, and the peak wavelength may be appropriately modified depending on the wavelength band of light of the color to be implemented in consideration of the saturation, etc. intended by the operator.

FIG. 25 is a simulation graph showing transmittance distribution by wavelength band of light emitted from each sub-pixel included in a pixel according to another embodiment of the present specification.

Referring to FIG. 25, a first red sub-pixel ER1 includes a color filter in which a first external metal layer including an Ag metal and having the thickness of 100 Å to 400 Å, a first dielectric layer including SiNₓ, SiO₂, or SiON, sputtered as ITO, IZO, or ZnO by CVD, and having the thickness of 1100 Å, an internal metal layer including an Ag metal and having the thickness of 200 Å to 800 Å, a second dielectric layer including SiNₓ, SiO₂, or SiON, sputtered as ZnO by CVD, and having the thickness of 1100 Å, and a second external metal layer including an Ag metal and having the thickness of 100 Å to 400 Å are stacked.

A second red sub-pixel ER2 includes a color filter in which a first external metal layer including an Ag metal and having the thickness of 100 Å to 400 Å, a first dielectric layer including SiNₓ, SiO₂, or SiON, sputtered as ITO, IZO, or ZnO by CVD, and having the thickness of 1200 Å, an internal metal layer including an Ag metal and having the thickness of 200 Å to 800 Å, a second dielectric layer including SiNₓ, SiO₂, or SiON, sputtered as ZnO by CVD, and having the thickness of 1200 Å, and a second external metal layer including an Ag metal and having the thickness of 100 Å to 400 Å are stacked.

A first blue sub-pixel EB1 includes a color filter in which a first external metal layer including an Ag metal and having the thickness of 100 Å to 400 Å, a first dielectric layer including SiNₓ, SiO₂, or SiON, sputtered as ITO, IZO, or ZnO by CVD, and having the thickness of 1600 Å, an internal metal layer including an Ag metal and having the thickness of 200 Å to 800 Å, a second dielectric layer including SiNₓ, SiO₂, or SiON, sputtered as ZnO by CVD, and having the thickness of 1100 Å, and a second external metal layer including an Ag metal and having the thickness of 100 Å to 400 Å are stacked.

A second blue sub-pixel EB2 includes a color filter in which a first external metal layer including an Ag metal and having the thickness of 100 Å to 400 Å, a first dielectric layer including SiNₓ, SiO₂, or SiON, sputtered as ITO, IZO, or ZnO by CVD, and having the thickness of 1800 Å, an internal metal layer including an Ag metal and having the thickness of 200 Å to 800 Å, a second dielectric layer including SiNₓ, SiO₂, or SiON, sputtered as ZnO by CVD, and having the thickness of 1200 Å, and a second external metal layer including an Ag metal and having the thickness of 100 Å to 400 Å are stacked.

A first green sub-pixel EG1 includes a color filter in which a first external metal layer including an Ag metal and having the thickness of 100 Å to 400 Å, a first dielectric layer including SiNₓ, SiO₂, or SiON, sputtered as ITO, IZO, or ZnO by CVD, and having the thickness of 2050 Å, an internal metal layer including an Ag metal and having the thickness of 200 Å to 800 Å, a second dielectric layer including SiNₓ, SiO₂, or SiON, sputtered as ZnO by CVD, and having the thickness of 1100 Å, and a second external metal layer including an Ag metal and having the thickness of 100 Å to 400 Å are stacked.

A second green sub-pixel EG2 includes a color filter in which a first external metal layer including an Ag metal and having the thickness of 100 Å to 400 Å, a first dielectric layer including SiNₓ, SiO₂, or SiON, sputtered as ITO, IZO, or ZnO by CVD, and having the thickness of 2100 Å, an internal metal layer including an Ag metal and having the thickness of 200 Å to 800 Å, a second dielectric layer including SiNₓ, SiO₂, or SiON, sputtered as ZnO by CVD, and having the thickness of 1200 Å, and a second external metal layer including an Ag metal and having the thickness of 100 Å to 400 Å are stacked.

It is confirmed that the peak wavelength is shifted as the thickness of the dielectric layer increases when compared the first red sub-pixel ER1 and the second red sub-pixel ER2, the first blue sub-pixel EB1 and the second blue sub-pixel EB2, and the first green sub-pixel EG1 and the second green sub-pixel EG2.

It is confirmed that light having the peak wavelength of 600 nm to 650 nm is emitted from the first red sub-pixel ER1 when the thickness of the dielectric layer is 1100 Å. Color coordinates are (0.621, 0.361). It is confirmed that light having the peak wavelength of 650 nm to 700 nm is emitted from the second red sub-pixel ER2 when the thickness of the dielectric layer is 1200 Å. Color coordinates are (0.595, 0.326).

It is confirmed that light having the peak wavelength of 400 nm to 450 nm is emitted from the first blue sub-pixel EB1 when the thickness of the dielectric layer is 1600 Å. Color coordinates are (0.153, 0.028). It is confirmed that light having the peak wavelength of 450 nm to 500 nm is emitted from the second blue sub-pixel EB2 when the thickness of the dielectric layer is 1800 Å. Color coordinates are (0.127, 0.079).

It is confirmed that light having the peak wavelength of 500 nm to 525 nm is emitted from the first green sub-pixel EG1 when the thickness of the dielectric layer is 2050 Å. Color coordinates are (0.165, 0.674). It is confirmed that light having the peak wavelength of 525 nm to 550 nm is emitted from the second green sub-pixel EG2 when the thickness of the dielectric layer is 2100 Å. Color coordinates are (0.209, 0.718).

The display panel including the color filter according to the embodiment may implement colors having the color coordinates. It is possible to increase the color gamut according to the display panel. The display device including the display panel according to the embodiments may have increased luminance and efficiency, thereby reducing power consumption and may be driven at low power. In addition, it is possible to increase a lifetime and enhance light extraction characteristics.

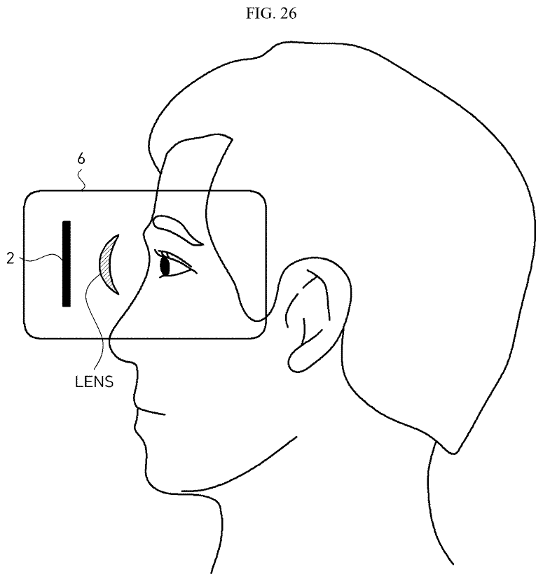

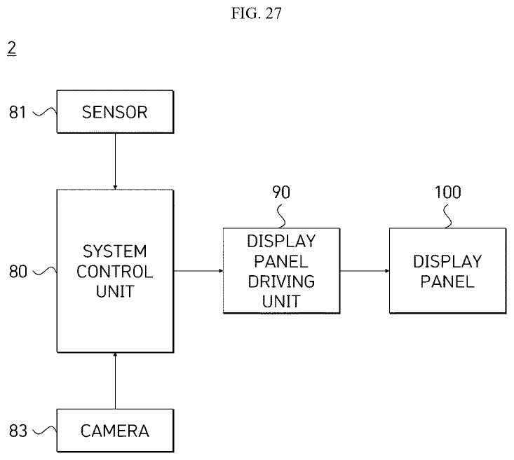

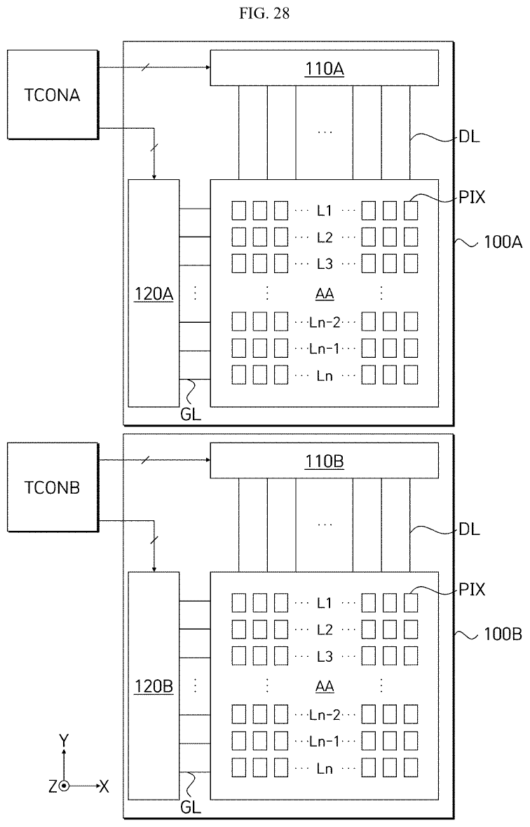

FIG. 26 is a view schematically showing a virtual reality device. FIG. 27 is a block diagram showing a display device according to one embodiment of the present specification. FIG. 28 is a view specifically showing a display driving unit and a display panel shown in FIG. 27.

Referring to FIGS. 26 and 27, a user sees a three-dimensional image displayed on a screen 2 through an eyepiece LENS. For example, the eyepiece LENS may be a fisheye lens.

The screen 2 may include a system control unit 80, a display driving unit 90, a display panel 100, etc.

The system control unit 80 may be connected to a sensor 81, a camera 83, and the like. The system control unit 80 may further include an external device interface connected to a memory or an external video source, a user interface for receiving user commands, a power supply unit for generating power, and the like. The external device interface, the user interface, the power supply unit, and the like are omitted from the drawing. The external device interface can be implemented as various known interface modules, such as a universal serial bus (USB) and a high definition multimedia interface (HDMI).

The sensor 81 may include various sensors, such as a gyro sensor and an acceleration sensor. The sensor 81 may transmit outputs of various sensors to the system control unit 80. The system control unit 80 may receive the output of the sensor 81 and move pixel data of images displayed on a screen in synchronization with the user's movement.

The display driving unit 90 may include a drive IC (SDIC) and a gate driver (GIP). When receiving pixel data of input images from the system control unit 80, the display driving unit 90 may write the pixel data to pixels of the display panel 100.

Referring to FIG. 28, the display panel 100 may include a first display panel 100A on which a left-eye image is displayed and a second display panel 100B on which a right-eye image is displayed.

In the display driving unit 90, data drivers 110A and 110B and gate drivers 120A and 120B are separated for each of the display panel 100A and 100B, and a timing controller TCON may be shared with the display panel driving units of the display panels 100A and 100B. Alternatively, a plurality of timing controllers TCONA, TCONB may be connected one-to-one to the display panel driving units of the display panels 100A and 100B.

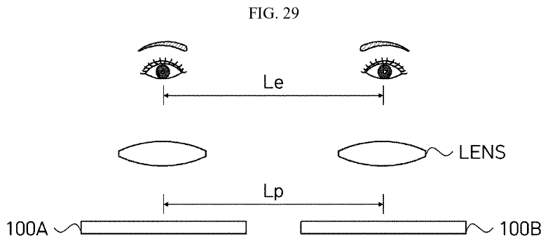

FIG. 29 is a view showing a distance between first and second display panels shown in FIG. 28.

Referring to FIG. 29, each of the first and second display panels 100A and 100B can be implemented as an organic light emitting diode (hereinafter referred to as “OLED”) display panel that has a fast response time, an excellent color gamut, and a wide viewing angle. In the case of an eye glasses-type display (EGD), the display panels 100A and 100B can be implemented as transparent OLED display panels.

The first and second display panels 100A and 100B may be manufactured separately and disposed to be spaced apart from each other. Although a distance between the center of the pixel array of the first display panel 100A and the center of the pixel array of the second display panel 100B may be substantially the same as a distance Le between the user's eyes, the present invention is not necessarily limited thereto.

When the pixel arrays of the display panels 100A and 100B are separated and the distance between the centers of the pixel arrays matches the distance between the left and right eyes of the user, the wide viewing angle can be implemented, and the three-dimensional effect can be greatly improved. The pupil of the user's left eye may match the center of the first pixel array of the first display panel 100A, and the pupil of the user's right eye may match the center of the second pixel array of the second display panel 100B. In a personal immersion device, an eyepiece LENS may be present between the user's eyes and the display panel. When the user views images displayed on the display panels 100A and 100B through the eyepiece LENS, the user may see images that are 4 to 5 times larger than actual screens displayed on the display panels 100A and 100B.

According to the present specification, it is possible to improve a color gamut of a display panel.

A display device including the display panel according to the present specification may have improved luminance and efficiency, thereby reducing power consumption and can be driven at low power. In addition, it is possible to increase a lifetime and enhance light extraction characteristics.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate;
a plurality of light emitting elements disposed on the substrate; and
a plurality of color filters disposed on the plurality of light emitting elements and having different thicknesses,
wherein each of the plurality of color filters includes:
a metal layer including a first external metal layer and a second external metal layer; and
a dielectric layer disposed between the first external metal layer and the second external metal layer.

2. The display device of claim 1, wherein the dielectric layer is disposed in contact with the first external metal layer and the second external metal layer and includes a transparent conductive oxide.

3. The display device of claim 2, wherein the metal layer includes an internal metal layer disposed between the first external metal layer and the second external metal layer, and
the dielectric layer includes a first dielectric layer disposed between the first external metal layer and the internal metal layer, and a second dielectric layer disposed between the internal metal layer and the second external metal layer.

4. The display device of claim 3, wherein the metal layer includes a first internal metal layer and a second internal metal layer that are disposed between the first external metal layer and the second external metal layer, and
the dielectric layer includes a first dielectric layer disposed between the first external metal layer and the first internal metal layer, a second dielectric layer disposed between the first internal metal layer and the second internal metal layer, and a third dielectric layer disposed between the second internal metal layer and the second external metal layer.

5. The display device of claim 3, wherein a thickness of the second external metal layer is 50% to 150% of a thickness of the first external metal layer, and
a thickness of the second dielectric layer is 50% to 150% of a thickness of the first dielectric layer.

6. The display device of claim 5, wherein a thickness of the internal metal layer is 50% to 150% of a sum of a thickness of the first external metal layer and a thickness of the second external metal layer.

7. The display device of claim 6, wherein a thickness of the first dielectric layer is 275% to 2100% of a thickness of the first external metal layer.

8. The display device of claim 7, wherein a thickness of the first dielectric layer is 275% to 1200% of a thickness of the first external metal layer.

9. The display device of claim 7, wherein a thickness of the first dielectric layer is 512.5% to 2100% of a thickness of the first external metal layer.

10. The display device of claim 7, wherein a thickness of the first dielectric layer is 375% to 1800% of a thickness of the first external metal layer.

11. The display device of claim 7, wherein a thickness of the first external metal layer ranges from 100 Å to 400 Å.

12. The display device of claim 3, wherein the plurality of color filters include a first color filter, a second color filter, and a third color filter, each of which implements any one of red, green, and blue in a non-overlapping manner, and
a thickness of a first external metal layer of the second color filter is 50% to 150% of a thickness of a first external metal layer of the first color filter.

13. The display device of claim 12, wherein the plurality of light emitting elements include a first light emitting element corresponding to the first color filter, a second light emitting element corresponding to the second color filter, a third light emitting element corresponding to the third color filter, and a fourth light emitting element implementing a white color.

14. The display device of claim 12, wherein the first color filter implements a red color, the second color filter implements a green color, and the third color filter implements a blue color,
a thickness of the first dielectric layer of the second color filter is 170% to 191% of a thickness of the first dielectric layer of the first color filter, and
a thickness of the first dielectric layer of the third color filter is 125% to 164% of the thickness of the first dielectric layer of the first color filter.

15. The display device of claim 14, wherein a thickness of the first dielectric layer of the first color filter ranges from 1100 Å to 1200 Å.

16. The display device of claim 12, wherein the first color filter implements a red color, the second color filter implements a green color, and the third color filter implements a blue color,
the first color filter includes a 1-1 color filter and a 1-2 color filter, of which the first dielectric layers have different thicknesses,
the second color filter includes a 2-1 color filter and a 2-2 color filter, of which the first dielectric layers have different thicknesses, and
the third color filter includes a 3-1 color filter and a 3-2 color filter, of which the first dielectric layers have different thicknesses.

17. The display device of claim 16, wherein a peak wavelength of light of a color implemented by the 1-1 color filter differs from a peak wavelength of light of a color implemented by the 1-2 color filter,
a peak wavelength of light of a color implemented by the 2-1 color filter differs from a peak wavelength of light of a color implemented by the 2-2 color filter, and
a peak wavelength of light of a color implemented by the 3-1 color filter differs from a peak wavelength of light of a color implemented by the 3-2 color filter.

18. The display device of claim 1, wherein the metal layer includes a thickness stepped portion disposed between the color filters having different thicknesses or disposed to overlap at least one of the color filters having different thicknesses in a thickness direction.

19. The display device of claim 1, wherein a transmittance distribution graph of light emitted from the light emitting element and passing through the color filter includes a first full width at half maximum (FWHM),
a transmittance distribution graph of light emitted from the light emitting element and passing through the first external metal layer and the dielectric layer includes a second FWHM, and
the first FWHM is smaller than the second FWHM.

20. The display device of claim 1, wherein each of the plurality of light emitting elements includes an organic light emitting layer.
